(19) United States
(12) Patent Application Publication
(10) Pub. No.: US 2023/0153487 A1
(43) Pub. Date: May 18, 2023

(54) MACHINE-IMPLEMENTABLE METHOD AND SYSTEM FOR ENCODING/DECODING VARIABLES IN ENGINEERING PROBLEMS

(71) Applicant: UNIVERSITEIT GENT, Gent (BE)

(72) Inventor: Philippe CHEVALIER, San Diego, CA (US)

(21) Appl. No.: 17/454,953

(22) Filed: Nov. 15, 2021

Related U.S. Application Data
(60) Provisional application No. 63/263,375, filed on Nov. 1, 2021.

(51) Int. Cl. G06F 30/23; G06K 9/62

(52) U.S. Cl. CPC G06F 30/23; G06K 9/6255; G06K 9/6224; G06K 9/6215

(57) ABSTRACT

The invention relates to a machine-implementable method, preferably a computer-implemented method, and system for the selection of a set of dependent and independent variables to form quantity equations for engineering problems. The method includes the encoding and decoding of dimensionless groups in an integer lattice. A preferred embodiment of the invention considers an integer lattice given by the cartesian product [symbol] ₂× [symbol] ⁷. The result of the method provides a system of quantity equations in the dependent and independent variables.

### FIELD OF THE INVENTION

The present invention relates to the selection of variables in engineering problems. More in particular, the present invention relates to a machine-implementable method and system for the selection of dependent and independent variables to form dimensionless quantity equations.

### BACKGROUND OF THE INVENTION

Some engineering problems have unknown sets of partial differential equations, and in those problems, one relies on the Buckingham theorem where dimensionless products of quantities are formed from the set of variables that the engineer has identified. Application of the theorem results in a reduction of the number k of dimensional variables in n dimensional units to a set of (k-r) dimensionless products where r is the rank of the n×k dimensional matrix. So, the engineer starts with a formal description of the problem f(x₁, . . . xₖ)=0, obtains a formal description of lower complexity, and thus reduces the computational load, through the equation F(Π₁, . . . Π₍ₖ₋ᵣ₎)=0 that can further be reduced to Π₁=g(Π₂,Π₃, . . . Π₍ₖ₋ᵣ₎). The problem is to make a good choice between the dependent and independent variables and subsequently their associated dimensionless products. Engineers for real world problems make use of the International System of Units (Système International d'Unités, SI) where the number of units is given by n=7. Most theoretical physicists use a length, mass, and time unit system where n=3.

Other sciences use different unit systems. In all problem descriptions, the scientists start with a finite set of base quantities. Those scientists agree by convention to associate to each base quantity a base unit. The convention of the International System of Units recommends scientists and engineers to use seven base quantities: length, mass, time, electric current, thermodynamic temperature, amount of substance, and luminous intensity. These quantities make up the International System of Quantities (ISQ).

The term dimension of a physical quantity refers to the expression of the dependence on the base quantities of a system of quantities as a product of powers of factors corresponding to the base quantities, omitting any numerical factor. The factors in the dimension are the symbols of the base quantities of the chosen system of quantities.

The symbols representing the dimensions of the base quantities in the ISQ are found in Table I.

TABLE I
Base quantities and symbols in the ISQ

| Base quantity | Symbol for dimension |
|---|---|
| length | L |
| mass | M |
| time | T |
| electric current | I |
| thermodynamic temperature | ⊖ |
| amount of substance | N |
| luminous intensity | J |

In the ISQ, we denote the dimension of a quantity Q by the equation:

dim Q=L^{α}M^{β}T^{γ}I^{δ}Θ^{ε}N^{ζ}Jη

The dimensional exponents of the known SI quantities take values in the following sets of integers:

α takes values from {−3, −2, −1, 0, 1, 2, 3, 4};

β takes values from {−3, −2, −1, 0, 1};

γ takes values from {−4, −3, −2, −1, 0, 1, 2, 3, 4, 6, 7, 10};

δ takes values from {−2, −1, 0, 1, 2, 3, 4};

ε takes values from {−4, −1, 0, 1};

ζ takes values from {−1, 0, 1}.

η takes values from {0, 1}.

For example, the dimension of the kind of quantity ‘energy’ E is denoted by:

dim E=L²M¹T⁻²I⁰Θ⁰N⁰J⁰.

The kind of quantity ‘energy’ is an element of the set of kinds of quantities to which different labels can be assigned: potential energy, electric energy, kinetic energy, thermal energy, . . . .

The formal mathematical framework for manipulating quantity equations is quantity calculus.

The simplest non-trivial quantity equation with lowest complexity has the form Z=f(Π)XY where X, Y, Z are kinds of physical quantities and f(H) is a function of a dimensionless quantity H. For example, Newton's law as a quantity equation is given by the equation: force=mass×acceleration.

U.S. Pat. No. 6,718,288 B1 relates to a method for determining a transfer function relating a critical to quality (CTQ) parameter to key parameters in a design for six sigma (DFSS) process wherein the method includes the determining of a dimensionless group containing a plurality of key control parameters (KCP) or key noise parameters (KNP). The generation of a functional transfer function according to U.S. Pat. No. 6,718,288 B1 requires the determination of dimensionless groups as exemplified in the flowchart of the method. An exemplary embodiment of the invention disclosed in U.S. Pat. No. 6,718,288 B1 provides a method within a DFSS process to develop semi-empirical transfer functions using numerical analysis and experimentation.

Unlike U.S. Pat. No. 6,718,288 B1, the present invention discloses a Euclidean lattice method that allows an efficient selection of the dependent and independent variables for constructing dimensionless groups.

### SUMMARY OF THE INVENTION

The present invention is concerned with methods that allow the selection of a set or sets of dependent and independent variables in engineering problems of a kind.

According to the present invention, there is provided a machine-implementable method and system for the selection of dependent and independent variables to form dimensionless quantity equations. The present invention makes use of encoding and decoding prescriptions using number and lattice theory. Specifically, this is done using integer factorization techniques. These integer factorization techniques are based on well-established computer efficient methods. Applying the disclosed method yields substantially superior selection of dependent and independent variables that allows sets of equations to be set up for a given engineering problem.

In a first aspect, the invention relates to a machine-implementable method, preferably a computer-implemented method, for forming quantity equations from a selection of a set or sets of dependent and independent variables, comprising the steps of:
a) defining an input from a selection of a set or sets of dependent and independent variables, the input comprising a list of quantities, for example physical quantities;
b) processing said input, comprising the steps of encoding and decoding of dimensionless groups in an integer lattice, preferably using integer factorization techniques, thereby obtaining a system of quantity equations, the quantity equations comprising the quantities; and,
c) presenting the system of quantity equations as output.

In some preferred embodiments, step a) comprises the steps of:
choosing a list of quantities by selecting and ordering n base quantities;
selecting w quantities from the said list of quantities to be analyzed where w is a natural number; and,
comparing the w quantities to a ‘kind of quantity’ database to determine the corresponding w integer lattice points of [symbol] ₂× [symbol] ⁿ.

In some preferred embodiments, a quantity is selected that maps to the orbit representative with integer lattice point x=(0|n, n−1, . . . ,1) of [symbol] ₂× [symbol] ⁿ of largest cardinality equal to the order 2(2ⁿn!) of the integer lattice [symbol] ₂× [symbol] ⁿ.

In some preferred embodiments, step b) comprises the steps of:
calculating for each of the w integer lattice points their respective w orbit representative orb(xᵢ), by taking the absolute value of the coordinates of the integer lattice point xᵢ=(x₀ⁱ|x₁ⁱ, . . . ,xₙⁱ), sorting them in decreasing order and renaming the coordinates such that orb(xᵢ)=(z₀ⁱ|z₁ⁱ, . . . ,zηⁱ) where z₁ⁱ≥z₂ⁱ≥ . . . ≥zₙⁱ and where i∈{1, . . . , w};
calculating for the w orbit representatives their respective degree dᵢ, where i∈{1, . . . , w};
identifying the orbit representative with the largest degree, denoting it y, and recalling its associated integer lattice point denoted as xₛ, such that y=orb(xₛ);
encoding each orbit representative orb(xᵢ) using the prescription:

$$G ( orb ( {x}_{i} ) ) := {( - 1 )}^{{z}_{0}^{i}} {p}_{1}^{{z}_{1}^{i}} ⋯ {p}_{n}^{{z}_{n}^{i}}$$

where pᵢ^{z}^{ᵢ} is the zᵢ-th power of the i-th prime number and where i∈{1, . . . , w};
generating the divisors sets of the w integers G(orb(xᵢ));
performing the m-factorization of the integer G(orb(xᵢ)) in distinct factors Fⱼ where j∈ {1, . . . , m},
calculating the prime factorization of each distinct factor Fᵢ;
decoding each m-factorization of the integer G(orb(xᵢ)) following the prescription:

$${F}_{j} := {( - 1 )}^{{z}_{0}^{j}} {p}_{1}^{{z}_{1}^{j}} ⋯ {p}_{n}^{{z}_{n}^{j}} \to ( {z}_{0}^{j} \vert {z}_{1}^{j} , ⋯ , {z}_{n}^{j} )$$

to obtain an additive partitioning using the respective prime factorizations of each distinct factor Fⱼ and replacing the multiplication operator‘x’ by the addition operator ‘+’ obtaining (m+1)-ary vector equations in the integer lattice [symbol] ₂× [symbol] ⁿ;
calculating the (n+1)×(n+1) signed permutation matrix P that maps the orbit representative y to the integer lattice point xₛ of [symbol] ₂× [symbol] ⁿ such that y=P [symbol] where [symbol] is the transposed vector of the integer lattice point xₛ; and,
multiplying each (m+1)-ary vector equation with the (n+1)×(n+1) signed permutation matrix P to obtain the final system of vector equations in the integer lattice [symbol] ₂× [symbol] ⁿ.

In some preferred embodiments, step b) comprises the steps of:
selecting the w integers G(orb(xᵢ));
ordering the divisors sets of the integers G(orb(xᵢ)) in their subsets of equal degree;
building a division lattice for each of the integers G(orb(xᵢ)) by stacking the subsets from low to high degree; and,
taking the union of the w division lattices.

In some preferred embodiments, step b) comprises the steps of:
selecting the p-norm;
calculating the p-norm between all the lattice points generated by the union of the division lattices; and,
visualizing the Euclidean graph for said p-norm of all the lattice points generated by said union of the division lattices.

In some preferred embodiments, step b) comprises the steps of:
selecting the 2-norm;
calculating the 2-norm between all the lattice points generated by the union of the division lattices; and,
visualizing the Euclidean graph for said 2-norm of all the lattice points generated by said union of the division lattices.

In some preferred embodiments, step b) comprises the steps of:
selecting the square of the 2-norm;
calculating the square of the 2-norm between all the lattice points generated by the union of the division lattices; and,
visualizing the Euclidean graph for said square of the 2-norm of all the lattice points generated by said union of the division lattices.

In some preferred embodiments, step c) comprises the step of:
creating a system of equations from the vector equations of the integer lattice [symbol] ₂× [symbol] ⁿ, preferably wherein the system of equations comprises algebraic equations, and/or ordinary differential equations, and/or partial differential equations, and/or integro-differential equations.

In some preferred embodiments, step c) comprises the step of:
labelling the variables using a lexicon, preferably a lexicon of the SI database, for example the lexicon as provided in Tables III to XVIII.

In some preferred embodiments, the lexicon is based on another system of units than the SI database.

In some preferred embodiments, step c) comprises the steps of:
updating a global lexicon or dictionary with the output of the method as described herein, or embodiments thereof;
analyzing the results through viewing information, visualizations, graphs, tables, and the like; and,
optionally, providing extra information if the quantity equations are known.

In some preferred embodiments, said dimension n=7 with said ordered base vectors preferably being length, mass, time, electric current, thermodynamic temperature, amount of substance, and luminous intensity, starting from coordinate index 1 and ending with index 7, preferably wherein the coordinate index 0 is reserved for the tensor type of the physical quantity.

In some preferred embodiments, said dimension n=1 with said ordered base vectors preferably being length, starting from coordinate index 1 and ending with index 1, preferably wherein the coordinate index 0 is reserved for the tensor type of the physical quantity.

In some preferred embodiments, said dimension n=2 with said ordered base vectors preferably being length, and mass, starting from coordinate index 1 and ending with index 2, preferably wherein the coordinate index 0 is reserved for the tensor type of the physical quantity.

In some preferred embodiments, said dimension n=3 with said ordered base vectors preferably being length, mass, and time, starting from coordinate index 1 and ending with index 3, preferably wherein the coordinate index 0 is reserved for the tensor type of the physical quantity.

In some preferred embodiments, said dimension n=4 with said ordered base vectors preferably being length, mass, time, and electric current, starting from coordinate index 1 and ending with index 4, preferably wherein the coordinate index 0 is reserved for the tensor type of the physical quantity.

In some preferred embodiments, said dimension n=5 with said ordered base vectors preferably being length, mass, time, electric current, and thermodynamic temperature, starting from coordinate index 1 and ending with index 5, preferably wherein the coordinate index 0 is reserved for the tensor type of the physical quantity.

In some preferred embodiments, said dimension n=6 with said ordered base vectors preferably being length, mass, time, electric current, thermodynamic temperature, and amount of substance, starting from coordinate index 1 and ending with index 6, preferably wherein the coordinate index 0 is reserved for the tensor type of the physical quantity.

In a second aspect, the invention relates to the use of the method according to the first aspect, or embodiments thereof, for an engineering problem.

In a third aspect, the invention relates to a system for forming quantity equations from a selection of a set of independent variables, preferably for engineering problems, comprising a computing device that includes a computer-readable storage medium storing a computer program, the computer program being configured to cause the computer to perform the method according to the first aspect, or embodiments thereof.

### BRIEF DESCRIPTION OF THE FIGURES

The foregoing and the following detailed description are better understood when read in conjunction with the appended drawings. For the purposes of illustration, examples are shown in the drawings; however, the subject matter is not limited to the specific elements and instrumentalities disclosed.

FIG. 1 presents a perimeter histogram of the kind of quantity energy in the lattice [symbol] , with infinity norm s=3.

FIG. 2 presents a Hasse representation of the encoding/decoding of the orbit representative of the partial derivative of the power density with respect to time given by G(orb(z))=(−1)⁰2⁴3¹5¹7⁰11⁰13⁰17⁰=240.

FIG. 3 presents a Euclidean graph of 24 paths connecting 20 integer lattice points of the orbit representative (0|4,1,1,0,0,0,0) with lattice point radius proportional to the degree of the lattice point.

FIG. 4 presents a Hasse representation of the encoding/decoding of the orbit representative of the kind of quantity energy E=(0|2,2,1,0,0,0,0) given by G(orb(E))=(−1)⁰2²3²5¹7⁰11⁰13⁰17⁰=180.

FIG. 5 presents a Hasse representation of the encoding/decoding of the vector potential \vec{A} orbit representative z=(0|3,2,1,1,0,0,0) given by G(orb(z))=(−1)⁰2³3²5¹7¹11⁰13⁰17⁰=2520.

### DETAILED DESCRIPTION OF THE PREFERRED EMBODIMENT

Before the present method and products of the invention are described, it is to be understood that this invention is not limited to particular methods, uses, systems, or combinations described, as such methods, uses, systems, and combinations may, of course, vary. It is also to be understood that the terminology used herein is not intended to be limiting, since the scope of the present invention will be limited only by the appended claims.

As used herein, the singular forms “a”, “an”, and “the” include both singular and plural referents, unless the context clearly dictates otherwise.

The terms “comprising”, “comprises” and “comprised of” as used herein are synonymous with “including”, “includes” or “containing”, “contains”, and are inclusive or open-ended and do not exclude additional, non-recited members, elements, or method steps. It will be appreciated that the terms “comprising”, “comprises” and “comprised of” as used herein comprise the terms “consisting of”, “consists” and “consists of”.

The recitation of numerical ranges by endpoints includes all numbers and fractions subsumed within the respective ranges, as well as the recited endpoints.

The term “about” or “approximately” as used herein when referring to a measurable value such as a parameter, an amount, a temporal duration, and the like, is meant to encompass variations of +/−10% or less, preferably +/−5% or less, more preferably +/−1% or less, and still more preferably +/−0.1% or less of and from the specified value, insofar such variations are appropriate to perform in the disclosed invention. It is to be understood that the value to which the modifier “about” or “approximately” refers is itself also specifically, and preferably, disclosed.

Whereas the terms “one or more” or “at least one”, such as one or more or at least one member(s) of a group of members, is clear per se, by means of further exemplification, the term encompasses inter alia a reference to any one of said members, or to any two or more of said members, such as, e.g., any≥3, ≥4, ≥5, ≥6 or ≥7 etc. of said members, and up to all said members.

All references cited in the present specification are hereby incorporated by reference in their entirety. In particular, the teachings of all references herein specifically referred to are incorporated by reference.

Unless otherwise defined, all terms used in disclosing the invention, including technical and scientific terms, have the meaning as commonly understood by one of ordinary skill in the art to which this invention belongs. By means of further guidance, term definitions are included to better appreciate the teaching of the present invention.

In the following passages, different aspects of the invention are defined in more detail. Each aspect so defined may be combined with any other aspect or aspects unless clearly indicated to the contrary. In particular, any feature indicated as being preferred or advantageous may be combined with any other feature or features indicated as being preferred or advantageous.

Reference throughout this specification to “one embodiment” or “an embodiment” means that a particular feature, structure, or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to a person skilled in the art from this disclosure, in one or more embodiments. Furthermore, while some embodiments described herein include some but not other features included in other embodiments, combinations of features of different embodiments are meant to be within the scope of the invention, and form different embodiments, as would be understood by those in the art. For example, in the appended claims, any of the claimed embodiments can be used in any combination.

To clarify the disclosed invention, we recall some important mathematical definitions.

The term 1-norm of a lattice point z of [symbol] ⁿ, denoted by ∥z∥₁, is defined by the mathematical expression ∥z∥₁:=|z₁|+ . . . +|zₙ|.

The term 2-norm corresponds to the Euclidean norm of a lattice point z of [symbol] ⁿ, denoted by ∥z∥₂, is defined by the mathematical expression ∥z∥₂:=\sqrt{z₁²+ . . . +zₙ²}.

The term infinity norm or maximum norm of a lattice point z of [symbol] ⁿ, denoted by ∥z∥_{∞}, is defined by the mathematical expression

$${‖ z ‖}_{∞} := {max}_{i} \vert {z}_{i} \vert ,$$

where i∈{1, . . . ,n}.

The term p-norm of a lattice point z of [symbol] ⁿ, denoted by ∥z∥ₚ, is defined by the mathematical expression

$${‖ z ‖}_{p} = {( {{\sum }_{i = 1}}^{n} {\vert {z}_{i} \vert}^{p} )}^{\frac{1}{p}}$$

where p≥1.

The term hypercube is an n-dimensional analogue of a square (n=2) and a cube (n=3).

The term scalar product is defined by the mathematical expression x·y:=x₁y₁+ . . . +xₙyₙ=∥x∥₂∥y∥₂ cos θ, with θ the angle between x and y, elements of [symbol] ⁿ.

The canonical representation of a positive integer n is defined as:

$$n := {p}_{1}^{{n}_{1}} \cdot {p}_{2}^{{n}_{2}} ⋯ {p}_{k}^{{n}_{k}} = {{\prod }_{i = 1}}^{k} {p}_{i}^{{n}_{i}}$$

where p₁<p₂< . . . <Pₖ and pᵢ is prime and nᵢ is a positive integer.

The term signed permutation matrix is defined by a generalized permutation matrix whose nonzero entries are ±1, and are the integer generalized permutation matrices with integer inverse.

The term orbit representative, denoted orb(x), of the lattice point x of the integer lattice [symbol] ⁿ is a lattice point z, with coordinates (z₁,z₂, . . . ,zₙ) of the positive orthant of [symbol] ⁿ, in graded reverse lexicographic order where z₁≥z₂≥z₃ . . . zₙ, to which x can be mapped by an element of the automorphism of the integer lattice [symbol] ⁿ, denoted Aut( [symbol] ⁿ). The set Aut( [symbol] ⁿ) has n×n signed permutation matrices as elements.

The term degree of the orbit representative orb(x) is defined through the equation

deg(orb(x)):=z₁+z₂+ . . . +zₙ where z=(z₁,z₂, . . . ,zₙ)∈ [symbol] ⁿ.

The term word is a finite, infinite from left to right or two-sided infinite sequence of symbols taken in a finite set called alphabet. The sequence of symbols, from the totally ordered alphabet A={0,1,2, . . . , m}, of a word w=(w₁, w₂, . . . , wₙ), where wᵢ are the coordinates of the representative lattice point ordered in graded reverse lexicographic order and thus w₁≥w₂≥w₃≥ . . . ≥wₙ where wᵢ∈ [symbol] ₊.

The cardinality of the set{orb(x)}, labelled by the orbit representative orb(x) in the integer lattice [symbol] ⁿ, is defined through the equation:

$$card ( \{ orb ( x ) \} ) := {2}^{( n - {q}_{0} )} \frac{n !}{{q}_{0} ! {q}_{1} ! ⋯ {q}_{m} !} ,$$

where [q₀, q₁, . . . ,qₘ] represents an additive partition of the natural number n=q₀+q₁+ . . . +qₘ where the qᵢ be the number of letters of type i of the totally ordered alphabet A={0,1,2, . . . , m} in the coordinates of the orbit representative orb(x).

The number of distinct cardinalities for card({orb(x)}) that can occur in an integer lattice of dimension n is finite. These results are published in the OEIS A270950 with sequence: a(n)=1,1,2,5,9,12,20,29,40,53,76,99,132,172,216,270,341,750 . . . .

The largest known published value a(17)=750 occurs for an integer lattice with dimension n=17. The trivial cardinality for the origin being 1 is not counted in A270950. For engineering purposes, the dimensions vary from

n=2 to n=7.

The cardinalities of the orbits of Aut( [symbol] ²) are 1, 4, 8.

The cardinalities of the orbits of Aut( [symbol] ³) are 1, 6, 8, 12, 24, 48.

The cardinalities of the orbits of Aut( [symbol] ⁴) are 1, 8, 16, 24, 32, 48, 64, 96, 192, 384.

The cardinalities of the orbits of Aut( [symbol] ⁵) are 1, 10, 32, 40, 80, 160, 240, 320, 480, 640, 960, 1920, 3840.

The cardinalities of the orbits of Aut( [symbol] ⁶) are 1, 12, 60, 64, 120, 160, 192, 240, 384, 480, 960, 1280, 1440, 1920,2880, 3840,5760,7680, 11520,23040,46080.

The cardinalities of the orbits of Aut( [symbol] ⁷) are 1, 14, 84, 128, 168, 280, 448, 560, 672, 840, 896, 1680, 2240, 2688, 3360, 4480, 5376, 6720, 8960, 13440, 17920, 20160, 26880, 40320, 53760, 80640, 107520, 161280, 322560, 645120.

In a first aspect, the invention relates to a machine-implementable method, preferably a computer-implemented method, for forming quantity equations from a selection of sets of dependent and independent variables, comprising the steps of:
a) defining an input from a selection of a set or sets of dependent and independent variables, the input comprising a list of quantities, for example physical quantities;
b) processing said input, comprising the steps of encoding and decoding of dimensionless groups in an integer lattice, preferably using integer factorization techniques, thereby obtaining a system of quantity equations, the quantity equations comprising the quantities; and,
c) presenting the system of quantity equations as output.

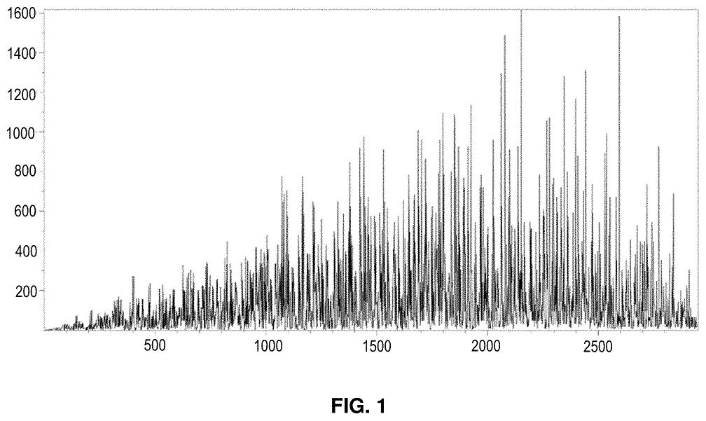

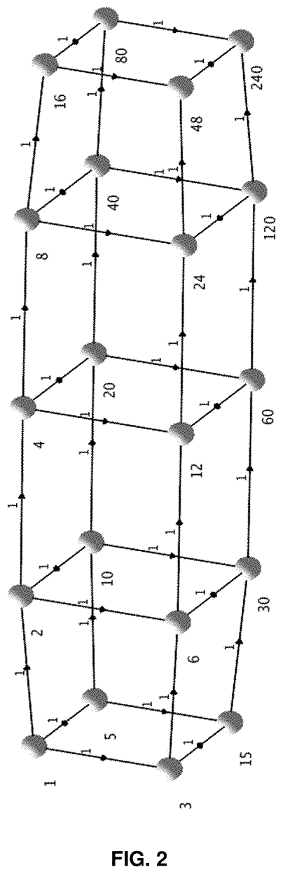

The disclosed method is significantly more advantageous in computing efficiency and efficacy as visualized by its output in FIG. 2. By way of comparison, a‘brute-force’ calculation based on walks in the integer lattice [symbol] ²× [symbol] ⁿ to explore relations between integer lattice points using statistical techniques results in a histogram given in FIG. 1. Moreover, the disclosed method contains an automatic selection of the independent variables, unlike the Buckingham theorem where the user must select the independent variables based on his experience or skill. This could lead to a false modelling of the engineering problem, requiring the re-iteration of all the calculations resulting in a waste of time and computing resources.

The disclosed method is computing efficient as it is based on low complexity, high performing, and well-established computer algorithms of number theoretic functions. The computer efficacy of the disclosed method is very high as it maps, based on the similitude principle, for example 1680 engineering problems to 1 canonical problem as given in a particular embodiment of the first order partial derivative of the power density with respect to time. The computer efficacy depends on the choice of the quantity and the number of base quantities. The computer efficacy ratios for quantities expressed in SI units are the finite set {28, 168, 256, 336, 560, 896, 1120, 1344, 1680, 1792, 3360, 4480, 5376, 6720, 8960,10752,13440,17920,26880,35840,40320,53760,80640, 107520, 161280, 215040, 322560, 645120, 1290240}.

In some embodiments, the method comprises the step of choosing a list of quantities by selecting and ordering n base quantities.

The base quantities may be chosen freely, but are preferably selected from the 7 base SI quantities. The present method allows for other choices to be made, resulting in a different meaning of the quantity equations. The present method mainly relates to the syntax of the quantity equations, while the semantics will depend on the chosen base quantities and the order chosen.

The semantics depend on the theory upon which the present method is applied.

In particular, the step of choosing a list of quantities and ordering n base quantities may be performed according to: time, length, electric current, mass, thermodynamic temperature, amount of substance, luminous intensity; based on the cardinality of the sets of values of each base quantity. More specifically, the set (or sets) of values with the largest cardinality are preferably first in the order as the largest cardinality becomes the exponent of the smallest prime number in the representation. The outlined strategy for ordering the n base quantities leads to higher efficiency as the numbers generated by the coding become smaller.

In some embodiments, the method comprises the step of selecting w quantities to be analyzed where w is a natural number.

In some embodiments, the method comprises the step of comparing the w quantities to a ‘kind of quantity’ database to determine the corresponding integer lattice point of [symbol] ₂× [symbol] ⁿ. As used herein, the term ‘kind of quantity’ database refers to records containing many relevant fields to the ‘kind of quantity’, such as the cardinality of the orbit representative, the infinity norm, the 1-norm, the orthant in the lattice name of the kind of quantity, an identifier within the orbit, the Conway identifier of the orbit, the lattice vertex coordinate, the sum of coordinates, etc.

In some preferred embodiments, quantity is selected that maps to the orbit representative with integer lattice point x=(0|n, n−1, . . . ,1) of [symbol] ₂× [symbol] ⁿ of largest cardinality equal to the order 2(2ⁿn!) of the integer lattice [symbol] ₂× [symbol] ⁿ. By selecting this specific integer lattice point, the smallest lattice can be created, on which all the symmetries of the lattice can act. The number of symmetries 2(2ⁿn!) corresponds to the number of signed permutation matrices that can act on the lattice points.

In some embodiments, the method comprises the step of calculating for each of the w integer lattice points their respective orbit representative orb(xᵢ), by taking the absolute value of the coordinates of the integer lattice point xᵢ=(x₀ⁱ|x₁ⁱ, . . . , xₙⁱ), sorting them in decreasing order, and renaming the coordinates such that orb(xᵢ)=(z₀ⁱ|z₁ⁱ, . . . ,zₙⁱ) where z₁ⁱ≥z₂ⁱ≥ . . . ≥zₙⁱ and where i∈{1, . . . , w}. The latter allows for classification of the kind of quantity in equivalence classes, which are represented by orbit representatives, and as such this classification contributes to reduce the number of cases to be studied.

In some embodiments, the method comprises the step of calculating for the w orbit representatives their respective degree dᵢ where i∈{1, . . . , w}.

In some embodiments, the method comprises the step of identifying the orbit representative with the largest degree, denoting it y, and recalling its associated integer lattice point denoted as x, such that y=orb(xₛ). The latter enables to identify the top of the lattice, which by definition belongs to the set of dependent variables.

In some embodiments, the method comprises the step of encoding each orbit representative orb(xᵢ) using the prescription:

$$G ( orb ( {x}_{i} ) ) := {( - 1 )}^{{z}_{0}^{i}} {p}_{1}^{{z}_{1}^{i}} ⋯ {p}_{n}^{{z}_{n}^{i}}$$

where pₗ^{z}^{ᵢ} is the zᵢ-th power of the i-th prime number and where i∈{1, . . . , w}. This encoding avoids the creation of ambiguity problems as a consequence of the factorization not being unique. A representative example of the ambiguity in the factorization of prime numbers in a Gaussian lattice is given by prime number 5=(1+2i)(1−2i).

In some embodiments, the method comprises the step of calculating the prime factorization of each distinct factor Fᵢ.

In some embodiments, the method comprises the step of decoding each m-factorization of the integer G(orb(xᵢ)) following the prescription:

$${F}_{j} := {( - 1 )}^{{z}_{0}^{j}} {p}_{1}^{{z}_{1}^{j}} ⋯ {p}_{n}^{{z}_{n}^{j}} \to ( {z}_{0}^{j} \vert {z}_{1}^{j} , ⋯ , {z}_{n}^{j} )$$

to obtain an additive partitioning using the respective prime factorizations of each distinct factor Fⱼ and replacing the multiplication operator ‘ x’ by the addition operator ‘+’ obtaining (m+1)-ary vector equations in the integer lattice [symbol] ²× [symbol] ⁿ.

The selected decoding is advantageous because it is based on a fundamental theorem of number theory: the unique prime factorization of a natural number.

In some embodiments, the method comprises the step of calculating the (n+1)×(n+1) signed permutation matrix P that maps the orbit representative y to the integer lattice point xₛ of [symbol] ₂× [symbol] ⁿsuch that y=P [symbol] where [symbol] is the transposed vector of the integer lattice point xₛ.

The step of calculating the (n+1)×(n+1) signed permutation matrix P mapping the orbit y to the integer lattice point xₛ of [symbol] ²× [symbol] ⁿ such that y=P [symbol] needs to be executed only once for all the vector equations of the engineering problem.

In some embodiments, the method comprises the step of multiplying each (m+1)-ary vector equations with the (n+1)×(n+1) signed permutation matrix P to obtain the final system of vector equations in the integer lattice [symbol] ²× [symbol] ⁿ.

In some preferred embodiments, the method comprises the steps of:
selecting the w integers G(orb(xᵢ));
ordering the divisors sets of the integers G(orb(xᵢ)) in their subsets of equal degree;
building a division lattice for each of the integers G(orb(xᵢ)) by stacking the subsets from low to high degree; and,
taking the union of the w division lattices.

The steps outlined above are functional to construct a Hasse diagram.

In some preferred embodiments, the method comprises the steps of:
selecting the p-norm;
calculating the p-norm between all the lattice points generated by the union of the division lattices; and,
visualizing the Euclidean graph for said p-norm of all the lattice points generated by said union of the division lattices.

In some preferred embodiments, the method comprises the steps of:
selecting the 2-norm;
calculating the 2-norm between all the lattice points generated by the union of the division lattices; and,
visualizing the Euclidean graph for said 2-norm of all the lattice points generated by said union of the division lattices.

The 2-norm operator is employed as distance metric corresponding to the definition of the Euclidean distance as it defines the distance between two points in a Euclidean n-dimensional space.

In some preferred embodiments, the method comprises the steps of:
selecting the square of the 2-norm;
calculating the square of the 2-norm between all the lattice points generated by the union of the division lattices; and,
visualizing the Euclidean graph for said square of the 2-norm of all the lattice points generated by said union of the division lattices.

The square of the 2-norm is preferably employed as only integers are used instead of real numbers, which in turn translates in lower computation demand due to significant less memory usage.

In some preferred embodiments, the method comprises the step of:
creating a system of equations from the vector equations of the integer lattice [symbol] ₂× [symbol] ⁿ, preferably wherein the system of equations comprises algebraic equations, and/or ordinary differential equations, and/or partial differential equations, and/or integro-differential equations.

In some preferred embodiments, the method comprises the step of:
labelling the variables using a lexicon, preferably a lexicon of the SI database, for example the lexicon as provided in Tables III to XVIII.

The usage of the lexicon as provided in Tables III to XVIII referring to the present status of all published SI physical quantities supports the user to provide (semantic) meaning to the equations generated by the computer.

In some preferred embodiments, the lexicon is based on another system of units than the SI database.

Another system of units is the MKSA system where only 4 base quantities are used for the description of engineering problems. NIST proposed a 7 base quantity system using: frequency, velocity, action, electric charge, heat capacity, amount of substance and luminous intensity. In the NIST system the kind of quantity energy has the coordinate (0|1,0,1,0,0,0,0) with code=6 instead of the SI coordinate (0|2,1,−2,0,0,0,0) with code=180. It is particularly advantageous to perform the choice of NIST versus the SI system, as its code results in a smaller number, which in turns allows for the energy to become an independent variable in many engineering problems.

In some preferred embodiments, step c) comprises one or more of the steps of:
updating a global lexicon or dictionary with the output of the method as described herein, or embodiments thereof;
analyzing the results through viewing information, visualizations, graphs, tables, and the like; and,
optionally, providing extra information if the quantity equations are known.

The visualization step provides the user with a pictorial approach to the diagrams instead of the algebra. This visualization allows a holistic approach to the engineering problem. After the results have been obtained, they can be added to the global lexicon or dictionary. The end-user can view information, visualizations, graphs, tables, etc. related to the quantity equation. If the quantity equation is known, extra information can be provided.

In some preferred embodiments, said dimension n=7 with said ordered base vectors preferably being length, mass, time, electric current, thermodynamic temperature, amount of substance, and luminous intensity, starting from coordinate index 1 and ending with index 7, preferably wherein the coordinate index 0 is reserved for the tensor type of the physical quantity.

The selection of base quantities complies to the present internationally accepted baseline (SI system) for science reporting.

In some preferred embodiments, said dimension n=1 with said ordered base vectors preferably being length, starting from coordinate index 1 and ending with index 1, preferably wherein the coordinate index 0 is reserved for the tensor type of the physical quantity.

The selection above is employed by theoretical physicists.

In some preferred embodiments, said dimension n=2 with said ordered base vectors preferably being length, and mass, starting from coordinate index 1 and ending with index 2, preferably wherein the coordinate index 0 is reserved for the tensor type of the physical quantity.

The selection above is employed by theoretical physicists.

In some preferred embodiments, said dimension n=3 with said ordered base vectors preferably being length, mass, and time, starting from coordinate index 1 and ending with index 3, preferably wherein the coordinate index 0 is reserved for the tensor type of the physical quantity.

The selection above is employed by the majority of theoretical physicists.

In some preferred embodiments, said dimension n=4 with said ordered base vectors preferably being length, mass, time, and electric current, starting from coordinate index 1 and ending with index 4, preferably wherein the coordinate index 0 is reserved for the tensor type of the physical quantity.

The selection above is employed by electrical engineers.

In some preferred embodiments, said dimension n=5 with said ordered base vectors preferably being length, mass, time, electric current, and thermodynamic temperature, starting from coordinate index 1 and ending with index 5, preferably wherein the coordinate index 0 is reserved for the tensor type of the physical quantity.

The selection above is employed by thermal engineers.

In some preferred embodiments, said dimension n=6 with said ordered base vectors preferably being length, mass, time, electric current, thermodynamic temperature, and amount of substance, starting from coordinate index 1 and ending with index 6, preferably wherein the coordinate index 0 is reserved for the tensor type of the physical quantity.

The selection above is employed by engineers not involved with photometric processes.

In a second aspect, the invention relates to the use of the method according to the first aspect, or embodiments thereof, for an engineering problem.

In a third aspect, the invention relates to a system for forming quantity equations from a selection of a set of dependent and independent variables, preferably for engineering problems, comprising a computing device that includes a computer-readable storage medium storing a computer program, the computer program being configured to cause the computer to perform the method according to the first aspect, or embodiments thereof.

Once the input quantity equation has been recognized, the disclosed method can be applied. This can be done on the same device, or by sending the input quantity equation to a processing system.

### EXAMPLES

### Example 1

In the present example, the disclosed method is applied, for the sake of simplicity, to a formula with w=1 where this quantity Q represents the first order partial derivative of the power density with respect to time, and where we postulate the quantity equation f(Q)=0. This case is a technical problem where the set of partial differential equations is unknown. It is technically relevant as this problem governs the future of power grids where wind turbine power and photovoltaic power is connected to the classical power grid where the power comes from a steam plant, a gas turbine, or a nuclear power plant. Those power conversions are dynamical variables that are distributed in space, and thus best described by the first order partial derivative of the power density with respect to time.

The disclosed method will search for the dependent and independent variables that are connected to the first order partial derivative of the power density with respect to time.

The dimension of the kind of quantity ‘time derivative of the power density’ is denoted by:

dim Q=L⁻¹M¹T⁻⁴I⁰Θ⁰N⁰J⁰.

To make a difference between physical quantities that transform like tens or pseudo-tensors, we consider the cartesian product [symbol] ₂× [symbol] ⁷, where [symbol] ₂=( [symbol] /2 [symbol] ) is the set {0,1}, and represent the kind of quantity ‘time derivative of the power density’ as the integer lattice point x=(0|−1,1,−4,0,0,0,0) and abbreviate it using the Conway notation to x=(0|−1,1, −4, 0⁴) when needed.

We encode the ‘time derivative of the power density’ by determining the orbit representative orb(x)=(0|4,1,1,0,0,0,0) that is an integer lattice point of the positive orthant of [symbol] ₂× [symbol] ⁷.

We map the integer lattice point of [symbol] ₂× [symbol] ⁷ to the integer G(orb(z)) of 7 [symbol] according to the following encoding prescription:

G(orb(z):=(−1)^{z}^{₀}p₁^{z}^{₁} . . . p₇^{z}^{₇}

of the orbit representative orb(z) in the lattice [symbol] ₂× [symbol] ⁷ where pᵢ^{z}^{ᵢ} is the zᵢ-th power of the i-th prime number, such that G((0|4,1,1,0,0,0,0))=(−1)⁰2⁴3¹5¹7⁰11⁰13⁰17⁰=240.

This number is known as a highly composite number. Its primorial factorization is 240=2³×30. The degree of the orbit representative orb(z) is calculated through the formula deg(orb(z))=z₁+z₂+ . . . +z₇ and thus deg(orb(x))=6.

The number of divisors of 240 is T(240)=20. The set of these divisors is 10 {1,2,3,4,5,6,8,10,12,15,16,20,24,30,40,48,60,80,120,240}.

We perform the factorization of the number 240 in m distinct factors and obtain the following: 9 factorizations in 2 distinct factors, 12 factorizations in 3 distinct factors, and 3 factorizations in 4 distinct factors. Factorizations of natural numbers from 1 to 10000 in m distinct factors is tabulated in the On-Line Encyclopaedia of Integer Sequences (OEIS) with identifier A045778.

We apply a decoding prescription that maps each divisor of G(orb(x)) being an element of Z to the positive orthant of the integer lattice [symbol] ₂× [symbol] ⁷:

G(orb(z)):=(−1)^{z}^{₀}p₁^{z}^{₁}. . . p₇^{z}^{₇}→(z₀,z₁. . . ,z₇)

This decoding creates a cluster of 20 integer lattice points in [symbol] ₂× [symbol] ⁷. The lattice points can be grouped in deg(orb(x))+1 distinct sets. These 7 sets ordered in increasing degree are:

S₀={(0|0,0,0,0,0,0,0)},

S₁={(0|1,0,0,0,0,0,0), (0|0,1,0,0,0,0,0), (0|0,0,1,0,0,0,0)},

S₂={(0|2,0,0,0,0,0,0), (0|1,1,0,0,0,0,0), (0|1,0,1,0,0,0,0), (0|0,1,1,0,0,0,0)},

S₃={(0|3,0,0,0,0,0,0), (0|2,1,0,0,0,0,0), (0|2,0,1,0,0,0,0), (0|1,1,1,0,0,0,0)},

S₄={(0|4,0,0,0,0,0,0), (0|3,1,0,0,0,0,0), (0|3,0,1,0,0,0,0), (0|2,1,1,0,0,0,0)},

S₅={(0|4,1,0,0,0,0,0), (0|4,0,1,0,0,0,0), (0|3,1,1,0,0,0,0)},

S₆={(0|4,1,1,0,0,0,0)}.

The visualization of the Hasse lattice containing the 7 sets is given in FIG. 2.

Each m-factoring yields an additive partitioning of the orbit representative orb(x) that is equivalent to a multiplicative (m+1)-ary equation.

The 4-factoring results in 3 quinary equations. The factorizations are:

240=2×3×4×10=2×3×5×8=2×4×5×6

The decoding prescription followed by the partitioning prescription results in 3 equations:

(0|4,1,1,0,0,0,0)=(0|0,0,0,0,0,0,0)+(0|1,0,0,0,0,0,0)+(0|0,1,0,0,0,0,0)+(0|2,0,0,0,0,0,0)+(0|1,0,1,0,0,0,0) Equation 1:

(0|4,1,1,0,0,0,0)=(0|0,0,0,0,0,0,0)+(0|1,0,0,0,0,0,0)+(0|0,1,0,0,0,0,0)+(0|0,0,1,0,0,0,0)+(0|3,0,0,0,0,0,0) Equation 2

(0|4,1,1,0,0,0,0)=(0|0,0,0,0,0,0,0)+(0|1,0,0,0,0,0,0)+(0|2,0,0,0,0,0,0)+(0|0,0,1,0,0,0,0)+(0|1,1,0,0,0,0,0) Equation 3

The 3-factoring results in 12 quaternary equations. The factorizations are:

$$240 = 2 \times 3 \times 40 = 2 \times 4 \times 30 = 2 \times 5 \times 24 = 2 \times 6 \times 20 = 2 \times 8 \times 15 = 2 \times 10 \times 12 = 3 \times 4 \times 20 = 3 \times 5 \times 16 = 3 \times 8 \times 10 = 4 \times 5 \times 12 = 4 \times 6 \times 10 = 5 \times 6 \times 8$$

The decoding prescription followed by the partitioning prescription results in 12 equations:

(0|4,1,1,0,0,0,0)=(0|0,0,0,0,0,0,0)+(0|1,0,0,0,0,0,0)+(0|0,1,0,0,0,0,0)+(0|3,0,1,0,0,0,0) Equation 1

(0|4,1,1,0,0,0,0)=(0|0,0,0,0,0,0,0)+(0|1,0,0,0,0,0,0)+(0|2,0,0,0,0,0,0)+(0|1,1,1,0,0,0,0) Equation 2

(0|4,1,1,0,0,0,0)=(0|0,0,0,0,0,0,0)+(0|1,0,0,0,0,0,0)+(0|0,0,1,0,0,0,0)+(0|3,1,0,0,0,0,0) Equation 3

(0|4,1,1,0,0,0,0)=(0|0,0,0,0,0,0,0)+(0|1,0,0,0,0,0,0)+(0|1,1,0,0,0,0,0)+(0|2,0,1,0,0,0,0) Equation 4

(0|4,1,1,0,0,0,0)=(0|0,0,0,0,0,0,0)+(0|1,0,0,0,0,0,0)+(0|3,0,0,0,0,0,0)+(0|0,1,1,0,0,0,0) Equation 5

(0|4,1,1,0,0,0,0)=(0|0,0,0,0,0,0,0)+(0|1,0,0,0,0,0,0)+(0|1,0,1,0,0,0,0)+(0|2,1,0,0,0,0,0) Equation 6

(0|4,1,1,0,0,0,0)=(0|0,0,0,0,0,0,0)+(0|0,1,0,0,0,0,0)+(0|2,0,0,0,0,0,0)+(0|2,0,1,0,0,0,0) Equation 7

(0|4,1,1,0,0,0,0)=(0|0,0,0,0,0,0,0)+(0|0,1,0,0,0,0,0)+(0|0,0,1,0,0,0,0)+(0|4,0,0,0,0,0,0) Equation 8

(0|4,1,1,0,0,0,0)=(0|0,0,0,0,0,0,0)+(0|0,1,0,0,0,0,0)+(0|3,0,0,0,0,0,0)+(0|1,0,1,0,0,0,0) Equation 9

(0|4,1,1,0,0,0,0)=(0|0,0,0,0,0,0,0)+(0|2,0,0,0,0,0,0)+(0|0,0,1,0,0,0,0)+(0|2,1,0,0,0,0,0) Equation 10

(0|4,1,1,0,0,0,0)=(0|0,0,0,0,0,0,0)+(0|2,0,0,0,0,0,0)+(0|1,1,0,0,0,0,0)+(0|1,0,1,0,0,0,0) Equation 11

(0|4,1,1,0,0,0,0)=(0|0,0,0,0,0,0,0)+(0|0,0,1,0,0,0,0)+(0|1,1,0,0,0,0,0)+(0|3,0,0,0,0,0,0) Equation 12

The 2-factoring results in 9 ternary equations. The factorizations are:

240=2×120=3×80=4×60=5×48=6×40=8×30=10×24=12×20=15×16

(0|4,1,1,0,0,0,0)=(0|0,0,0,0,0,0,0)+(0|1,0,0,0,0,0,0)+(0|3,1,1,0,0,0,0) Equation 1

(0|4,1,1,0,0,0,0)=(0|0,0,0,0,0,0,0)+(0|0,1,0,0,0,0,0)+(0|4,0,1,0,0,0,0) Equation 2

(0|4,1,1,0,0,0,0)=(0|0,0,0,0,0,0,0)+(0|2,0,0,0,0,0,0)+(0|2,1,1,0,0,0,0) Equation 3

(0|4,1,1,0,0,0,0)=(0|0,0,0,0,0,0,0)+(0|1,0,0,0,0,0,0)+(0|3,1,1,0,0,0,0) Equation 4

(0|4,1,1,0,0,0,0)=(0|0,0,0,0,0,0,0)+(0|0,0,1,0,0,0,0)+(0|4,1,0,0,0,0,0) Equation 5

(0|4,1,1,0,0,0,0)=(0|0,0,0,0,0,0,0)+(0|3,0,0,0,0,0,0)+(0|1,1,1,0,0,0,0) Equation 6

(0|4,1,1,0,0,0,0)=(0|0,0,0,0,0,0,0)+(0|1,0,1,0,0,0,0)+(0|3,1,0,0,0,0,0) Equation 7

(0|4,1,1,0,0,0,0)=(0|0,0,0,0,0,0,0)+(0|2,1,0,0,0,0,0)+(0|2,0,1,0,0,0,0) Equation 8

(0|4,1,1,0,0,0,0)=(0|0,0,0,0,0,0,0)+(0|0,1,1,0,0,0,0)+(0|4,0,0,0,0,0,0) Equation 9

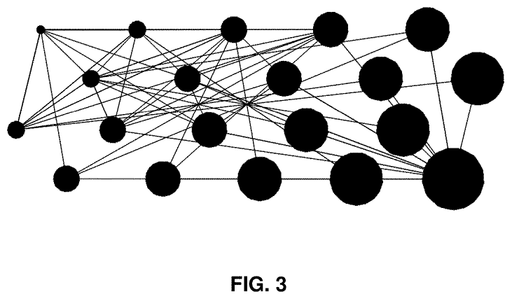

The visualization of the Euclidean graph formed by the above 20 vertices and their 24 canonical equations is given in FIG. 3, where the equations are represented by paths connecting the integer points associated to the terms of the equation in the order from left to right.

The cardinality in [symbol] ₂× [symbol] ⁷ of the set {orb(x)}, labelled by the orbit representative orb(x)=(0|4,1,1,0,0,0,0), is given by the equation

$$card ( \{ orb ( x ) \} ) := 2 ( \frac{{2}^{( 7 - 4 )} 7 !}{1 ! 2 ! 4 !} ) = 1680$$

that represents the number of distinct elements in the set {orb(x)}.

The disclosed method achieves the modelling of 1680 different engineering problems to be expressed in 1 structure containing 24 canonical vector equations based on their geometrical similitude. So, instead of solving 1680×24=40320 vector equations in the computer, we reduce the problem to solving only 24 vector equations. This has a significant impact on computing time and power usage.

To each of the 1680 vectors y, representing the individual engineering problems, exists a unique signed permutation matrix P that maps the lattice point x=(0|4,1,1,0,0,0,0) to the lattice point y.

For the case of the time-derivative of the power density we find the 8×8 signed permutation matrix P:

$$P = ( \begin{matrix}1 & 0 & 0 & 0 & 0 & 0 & 0 & 0 \\ 0 & 0 & 0 & - 1 & 0 & 0 & 0 & 0 \\ 0 & 1 & 0 & 0 & 0 & 0 & 0 & 0 \\ 0 & - 1 & 0 & 0 & 0 & 0 & 0 & 0 \\ 0 & 0 & 0 & 0 & 1 & 0 & 0 & 0 \\ 0 & 0 & 0 & 0 & 0 & 1 & 0 & 0 \\ 0 & 0 & 0 & 0 & 0 & 0 & 1 & 0 \\ 0 & 0 & 0 & 0 & 0 & 0 & 0 & 1\end{matrix} )$$

Applying the matrix P to each of the 24 vector equations, yields a new set of 24 vector equations that provides the structure searched for by the engineer/scientist. The semantic interpretation of the vector equations relies on the experience of the engineer/scientist. The engineer/scientist has the possibility to connect to a database containing a lexicon/dictionary of known quantities with their associated lattice point cluster.

In the present example, we list searched equations for the case of the first order partial derivative of the power density with respect to time, that is equivalent to the second order derivative of the energy density W with respect to time and its associated dimensional equation, where the symbols are taking from the dictionary or lexicon (Table III to Table XVII) of the SI database and have the following interpretation: W the energy density,

$$\frac{\partial W}{\partial t} = \frac{P}{V}$$

being the partial derivative of the energy density with respect to time,

$$\frac{{\partial }^{2} W}{\partial {t}^{2}}$$

the second order partial derivative of the energy density with respect to time, r radius, t (proper) time, ωᵢ angular frequency, m mass, k wavevector, S action, V volume, P power and fᵢ (Π) i-th function of dimensionless variable Π.

In the present example, the following 24 non-trivial results are presented:

$$( 0 \vert - 1 , 1 , - 4 , 0 , 0 , 0 , 0 ) = ( 0 \vert 0 , 0 , 0 , 0 , 0 , 0 , 0 ) + ( 0 \vert 0 , 0 , - 1 , 0 , 0 , 0 , 0 ) + ( 0 \vert 0 , 1 , 0 , 0 , 0 , 0 , 0 ) + ( 0 \vert 0 , 0 , - 2 , 0 , 0 , 0 , 0 ) + ( 0 \vert - 1 , 0 , - 1 , 0 , 0 , 0 , 0 ) \qquad Equation 1$$

$$dimensional equation 1 : \frac{{\partial }^{2} W}{\partial {t}^{2}} = {f}_{1} ( \prod ) {ω}_{1} m {ω}_{2}^{2} \frac{\partial k}{\partial t}$$

$$( 0 \vert - 1 , 1 , - 4 , 0 , 0 , 0 , 0 = ( 0 \vert 0 , 0 , 0 , 0 , 0 , 0 , 0 ) + ( 0 \vert 0 , 0 , - 1 , 0 , 0 , 0 , 0 ) + ( 0 \vert 0 , 1 , 0 , 0 , 0 , 0 , 0 ) + ( 0 \vert - 1 , 0 , 0 , 0 , 0 , 0 , 0 ) + ( 0 \vert 0 , 0 , - 3 , 0 , 0 , 0 , 0 ) \qquad Equation 2$$

$$dimensional equation 2 : \frac{{\partial }^{2} W}{\partial {t}^{2}} = {f}_{2} ( \prod ) {ω}_{1} m k {ω}_{2}^{3}$$

$$( 0 \vert - 1 , 1 , - 4 , 0 , 0 , 0 , 0 ) = ( 0 \vert 0 , 0 , 0 , 0 , 0 , 0 , 0 ) + ( 0 \vert 0 , 0 , - 1 , 0 , 0 , 0 , 0 ) + ( 0 \vert 0 , 0 , - 2 , 0 , 0 , 0 , 0 ) + ( 0 \vert - 1 , 0 , 0 , 0 , 0 , 0 , 0 ) + ( 0 \vert 0 , 1 , - 1 , 0 , 0 , 0 , 0 ) \qquad Equation 3$$

$$dimension al equation 3 : \frac{{\partial }^{2} W}{\partial {t}^{2}} = {f}_{3} ( \prod ) {ω}_{1} {m}_{2}^{2} k \frac{\partial m}{\partial t}$$

$$( 0 \vert - 1 , 1 , - 4 , 0 , 0 , 0 , 0 ) = ( 0 \vert 0 , 0 , 0 , 0 , 0 , 0 , 0 ) + ( 0 \vert 0 , 0 , - 1 , 0 , 0 , 0 , 0 ) + ( 0 \vert 0 , 1 , 0 , 0 , 0 , 0 , 0 ) + ( 0 \vert - 1 , 0 , - 3 , 0 , 0 , 0 , 0 ) \qquad Equation 4$$

$$dimension al equation 4 : \frac{{\partial }^{2} W}{\partial {t}^{2}} = {f}_{4} ( \prod ) {ω}_{1} m \frac{{\partial }^{3} k}{\partial {t}^{3}}$$

$$( 0 \vert - 1 , 1 , - 4 , 0 , 0 , 0 , 0 ) = ( 0 \vert 0 , 0 , 0 , 0 , 0 , 0 , 0 ) + ( 0 \vert 0 , 0 , - 1 , 0 , 0 , 0 , 0 ) + ( 0 \vert 0 , 0 , - 2 , 0 , 0 , 0 , 0 ) + ( 0 \vert - 1 , 1 , - 1 , 0 , 0 , 0 , 0 ) \qquad Equation 5$$

$$dimension al equation 5 : \frac{{\partial }^{2} W}{\partial {t}^{2}} = {f}_{5} ( \prod ) {ω}_{1} {ω}_{2}^{2} ( \frac{S}{V} )$$

$$( 0 \vert - 1 , 1 , - 4 , 0 , 0 , 0 , 0 ) = ( 0 \vert 0 , 0 , 0 , 0 , 0 , 0 , 0 ) + ( 0 \vert 0 , 0 , - 1 , 0 , 0 , 0 , 0 ) + ( 0 \vert - 1 , 0 , 0 , 0 , 0 , 0 , 0 ) + ( 0 \vert 0 , 1 , - 3 , 0 , 0 , 0 , 0 ) \qquad Equation 6$$

$$dimensional equation 6 : \frac{{\partial }^{2} W}{\partial {t}^{2}} = {f}_{6} ( \prod ) {ω}_{1} k \frac{{\partial }^{3} m}{\partial {t}^{3}}$$

$$( 0 \vert - 1 , 1 , - 4 , 0 , 0 , 0 , 0 ) = ( 0 \vert 0 , 0 , 0 , 0 , 0 , 0 , 0 ) + ( 0 \vert 0 , 0 , - 1 , 0 , 0 , 0 , 0 ) + ( 0 \vert 0 , 1 , - 1 , 0 , 0 , 0 , 0 ) + ( 0 \vert 1 , 0 , - 2 , 0 , 0 , 0 , 0 ) \qquad Equation 7$$

$$dimensional equation 7 : \frac{{\partial }^{2} W}{\partial {t}^{2}} = {f}_{7} ( \prod ) {ω}_{1} \frac{{\partial }^{2} k}{\partial {t}^{2}} \frac{\partial m}{\partial t}$$

$$( 0 \vert - 1 , 1 , - 4 , 0 , 0 , 0 , 0 ) = ( 0 \vert 0 , 0 , 0 , 0 , 0 , 0 , 0 ) + ( 0 \vert 0 , 0 , - 1 , 0 , 0 , 0 , 0 ) + ( 0 \vert 0 , 0 , - 3 , 0 , 0 , 0 , 0 ) + ( 0 \vert - 1 , 1 , 0 , 0 , 0 , 0 , 0 ) \qquad Equation 8$$

$$dimensional equation 8 : \frac{{\partial }^{2} W}{\partial {t}^{2}} = {f}_{8} ( \prod ) {ω}_{1} {ω}_{2}^{3} \frac{\partial m}{\partial r}$$

$$( 0 \vert - 1 , 1 , - 4 , 0 , 0 , 0 , 0 ) = ( 0 \vert 0 , 0 , 0 , 0 , 0 , 0 , 0 ) + ( 0 \vert 0 , 0 , - 1 , 0 , 0 , 0 , 0 ) + ( 0 \vert - 1 , 0 , - 1 , 0 , 0 , 0 , 0 ) + ( 0 \vert 1 , 0 , - 2 , 0 , 0 , 0 , 0 ) \qquad Equation 9$$

$$dimensional equation 9 : \frac{{\partial }^{2} W}{\partial {t}^{2}} = {f}_{9} ( \prod ) {ω}_{1} \frac{{\partial }^{2} m}{\partial {t}^{2}} \frac{\partial k}{\partial t}$$

$$( 0 \vert - 1 , 1 , - 4 , 0 , 0 , 0 , 0 ) = ( 0 \vert 0 , 0 , 0 , 0 , 0 , 0 , 0 ) + ( 0 \vert 0 , 1 , 0 , 0 , 0 , 0 , 0 ) + ( 0 \vert 0 , 0 , - 2 , 0 , 0 , 0 , 0 ) + ( 0 \vert - 1 , 0 , - 2 , 0 , 0 , 0 , 0 ) \qquad Equation 10$$

$$dimensional equation 10 : \frac{{\partial }^{2} W}{\partial {t}^{2}} = {f}_{10} ( \prod ) m {ω}_{1}^{2} \frac{{\partial }^{2} k}{\partial {t}^{2}}$$

$$( 0 \vert - 1 , 1 , - 4 , 0 , 0 , 0 , 0 ) = ( 0 \vert 0 , 0 , 0 , 0 , 0 , 0 , 0 ) + ( 0 \vert 0 , 1 , 0 , 0 , 0 , 0 , 0 ) + ( 0 \vert - 1 , 0 , 0 , 0 , 0 , 0 , 0 ) + ( 0 \vert 0 , 0 , - 4 , 0 , 0 , 0 , 0 ) \qquad Equation 11$$

$$dimensional equation 11 : \frac{{\partial }^{2} W}{\partial {t}^{2}} = {f}_{11} ( \prod ) mk {ω}_{1}^{4}$$

$$( 0 \vert - 1 , 1 , - 4 , 0 , 0 , 0 , 0 ) = ( 0 \vert 0 , 0 , 0 , 0 , 0 , 0 , 0 ) + ( 0 \vert 0 , 1 , 0 , 0 , 0 , 0 , 0 ) + ( 0 \vert 0 , 0 , - 3 , 0 , 0 , 0 , 0 ) + ( 0 \vert - 1 , 0 , - 1 , 0 , 0 , 0 , 0 ) \qquad Equation 12$$

$$dimensional equation 12 : \frac{{\partial }^{2} W}{\partial {t}^{2}} = {f}_{12} ( \prod ) m {ω}_{1}^{3} \frac{\partial k}{\partial t}$$

$$( 0 \vert - 1 , 1 , - 4 , 0 , 0 , 0 , 0 ) = ( 0 \vert 0 , 0 , 0 , 0 , 0 , 0 , 0 ) + ( 0 \vert 0 , 0 , - 2 , 0 , 0 , 0 , 0 ) + ( 0 \vert - 1 , 0 , 0 , 0 , 0 , 0 , 0 ) + ( 0 \vert 0 , 1 , - 2 , 0 , 0 , 0 , 0 ) \qquad Equation 13$$

$$dimensional equation 13 : \frac{{\partial }^{2} W}{\partial {t}^{2}} = {f}_{13} ( \prod ) k {ω}_{1}^{2} \frac{{\partial }^{2} m}{\partial {t}^{2}}$$

$$( 0 \vert - 1 , 1 , - 4 , 0 , 0 , 0 , 0 ) = ( 0 \vert 0 , 0 , 0 , 0 , 0 , 0 , 0 ) + ( 0 \vert 0 , 0 , - 2 , 0 , 0 , 0 , 0 ) + ( 0 \vert 0 , 1 , - 1 , 0 , 0 , 0 , 0 ) + ( 0 \vert - 1 , 0 , - 1 , 0 , 0 , 0 , 0 ) \qquad Equation 14$$

$$dimensional equation 14 : \frac{{\partial }^{2} W}{\partial {t}^{2}} = {f}_{14} ( \prod ) {ω}_{1}^{2} \frac{\partial m}{\partial t} \frac{\partial k}{\partial t}$$

$$( 0 \vert - 1 , 1 , - 4 , 0 , 0 , 0 , 0 ) = ( 0 \vert 0 , 0 , 0 , 0 , 0 , 0 , 0 ) + ( 0 \vert - 1 , 0 , 0 , 0 , 0 , 0 , 0 ) + ( 0 \vert 0 , 1 , - 1 , 0 , 0 , 0 , 0 ) + ( 0 \vert 0 , 0 , - 3 , 0 , 0 , 0 , 0 ) \qquad Equation 15$$

$$dimensional equation 15 : \frac{{\partial }^{2} W}{\partial {t}^{2}} = {f}_{15} ( \prod ) k {ω}_{1}^{3} \frac{\partial m}{\partial t}$$

$$( 0 \vert - 1 , 1 , - 4 , 0 , 0 , 0 , 0 ) = ( 0 \vert 0 , 0 , 0 , 0 , 0 , 0 , 0 ) + ( 0 \vert 0 , 0 , - 1 , 0 , 0 , 0 , 0 ) + ( 0 \vert - 1 , 1 , - 3 , 0 , 0 , 0 , 0 ) \qquad Equation 16$$

$$dimensional equation 16 : \frac{{\partial }^{2} W}{\partial {t}^{2}} = {f}_{16} ( \prod ) {ω}_{1} \frac{\partial W}{\partial t}$$

$$( 0 \vert - 1 , 1 , - 4 , 0 , 0 , 0 , 0 ) = ( 0 \vert 0 , 0 , 0 , 0 , 0 , 0 , 0 ) + ( 0 \vert 0 , 1 , 0 , 0 , 0 , 0 , 0 ) + ( 0 \vert - 1 , 0 , - 4 , 0 , 0 , 0 , 0 ) \qquad Equation 17$$

$$dimensional equation 17 : \frac{{\partial }^{2} W}{\partial {t}^{2}} = {f}_{17} ( \prod ) m \frac{{\partial }^{4} k}{\partial {t}^{4}}$$

$$( 0 \vert - 1 , 1 , - 4 , 0 , 0 , 0 , 0 ) = ( 0 \vert 0 , 0 , 0 , 0 , 0 , 0 , 0 ) + ( 0 \vert 0 , 0 , - 2 , 0 , 0 , 0 , 0 ) + ( 0 \vert - 1 , 1 , - 2 , 0 , 0 , 0 , 0 ) \qquad Equation 18$$

$$dimensional equation 18 : \frac{{\partial }^{2} W}{\partial {t}^{2}} = {f}_{18} ( \prod ) {ω}_{1}^{2} W$$

$$( 0 \vert - 1 , 1 , - 4 , 0 , 0 , 0 , 0 ) = ( 0 \vert 0 , 0 , 0 , 0 , 0 , 0 , 0 ) + ( 0 \vert - 1 , 0 , 0 , 0 , 0 , 0 , 0 ) + ( 0 \vert 0 , 1 , - 4 , 0 , 0 , 0 , 0 ) \qquad Equation 19$$

$$dimensional equation 19 : \frac{{\partial }^{2} W}{\partial {t}^{2}} = {f}_{19} ( \prod ) k \frac{{\partial }^{4} m}{\partial {t}^{4}}$$

$$( 0 \vert - 1 , 1 , - 4 , 0 , 0 , 0 , 0 ) = ( 0 \vert 0 , 0 , 0 , 0 , 0 , 0 , 0 ) + ( 0 \vert 1 , - 1 , 0 , 0 , 0 , 0 , 0 ) + ( 0 \vert - 1 , 0 , - 3 , 0 , 0 , 0 , 0 ) \qquad Equation 20$$

$$dimensional equation 20 : \frac{{\partial }^{2} W}{\partial {t}^{2}} = {f}_{20} ( \prod ) \frac{\partial m}{\partial t} \frac{{\partial }^{3} k}{\partial {t}^{3}}$$

$$( 0 \vert - 1 , 1 , - 4 , 0 , 0 , 0 , 0 ) = ( 0 \vert 0 , 0 , 0 , 0 , 0 , 0 , 0 ) + ( 0 \vert 0 , 0 , - 3 , 0 , 0 , 0 , 0 ) + ( 0 \vert - 1 , 1 , - 1 , 0 , 0 , 0 , 0 ) \qquad Equation 21$$

$$dimensional equation 21 : \frac{{\partial }^{2} W}{\partial {t}^{2}} = {f}_{21} ( \prod ) {ω}_{1}^{3} ( \frac{S}{V} )$$

$$( 0 \vert - 1 , 1 , - 4 , 0 , 0 , 0 , 0 ) = ( 0 \vert 0 , 0 , 0 , 0 , 0 , 0 , 0 ) + ( 0 \vert - 1 , 0 , - 1 , 0 , 0 , 0 , 0 ) + ( 0 \vert 0 , 1 , - 3 , 0 , 0 , 0 , 0 ) \qquad Equation 22$$

$$dimensional equation 22 : \frac{{\partial }^{2} W}{\partial {t}^{2}} = {f}_{22} ( \prod ) \frac{\partial k}{\partial t} \frac{{\partial }^{3} m}{\partial {t}^{3}}$$

$$( 0 \vert - 1 , 1 , - 4 , 0 , 0 , 0 , 0 ) = ( 0 \vert 0 , 0 , 0 , 0 , 0 , 0 , 0 ) + ( 0 \vert 0 , 1 , - 2 , 0 , 0 , 0 , 0 ) + ( 0 \vert - 1 , 0 , - 2 , 0 , 0 , 0 , 0 ) \qquad Equation 23$$

$$dimensional equation 23 : \frac{{\partial }^{2} W}{\partial {t}^{2}} = {f}_{23} ( \prod ) \frac{{\partial }^{2} m}{\partial {t}^{2}} \frac{{\partial }^{2} k}{\partial {t}^{2}}$$

$$( 0 \vert - 1 , 1 , - 4 , 0 , 0 , 0 , 0 ) = ( 0 \vert 0 , 0 , 0 , 0 , 0 , 0 , 0 ) + ( 0 \vert - 1 , 1 , 0 , 0 , 0 , 0 , 0 ) + ( 0 \vert 0 , 0 , - 4 , 0 , 0 , 0 , 0 ) \qquad Equation 24$$

$$dimensional equation 24 : \frac{{\partial }^{2} W}{\partial {t}^{2}} = {f}_{24} ( \prod ) {ω}_{1}^{4} \frac{\partial m}{ω r}$$

$$Each of the 24 equations can be studied and solved using well - known mathematical techniques .$$

### Example 2

Another embodiment of the present invention is the application of the disclosed method to the kind of quantity energy E. The kind of quantity energy has the coordinates E=(0|2,1, −2,0,0,0,0) expressed using the 7 SI base units as m²·kg¹·s⁻²·A⁰·K⁰·mol⁰·cd⁰. Its orbit representative has the coordinate (0|2,2,1,0,0,0,0) in [symbol] ₂× [symbol] ⁷. The encoding of the orbit representative yields G((0|2,2,1,0,0,0,0))=(−1)⁰2²3²5¹7⁰11⁰13⁰17⁰=180.

This number is known as a highly composite number. Its primorial factorization is 180=6×30.

The number of divisors of 180 is τ(180)=18. The set of the divisors of 180 is {1,2,3,4,5,6,9,10,12,15,18,20,30,36,45,60,90,180}.

The decoding creates a cluster of 18 integer lattice points in [symbol] ₂× [symbol] ⁷.

The degree of the orbit representative is deg(orb(E))=5 resulting in 6 subsets of the divisors set of 180.

These 6 sets ordered in increasing degree are:

S₀={(0|0,0,0,0,0,0,0)},

S₁={(0|1,0,0,0,0,0,0), (0|0,1,0,0,0,0,0), (0|0,0,1,0,0,0,0)},

S₂={(0|2,0,0,0,0,0,0), (0|1,1,0,0,0,0,0), (0|0,2,0,0,0,0,0), (0|1,0,1,0,0,0,0), (0|0,1,1,0,0,0,0)}

S₃={(0|2,1,0,0,0,0,0), (0|1,2,0,0,0,0,0), (0|2,0,1,0,0,0,0), (0|1,1,1,0,0,0,0), (0|0,2,1,0,0,0,0)}

S₄={(0|2,2,0,0,0,0,0), (0|2,1,1,0,0,0,0), (0|1,2,1,0,0,0,0)},

S₅={(0|2,2,1,0,0,0,0)}.

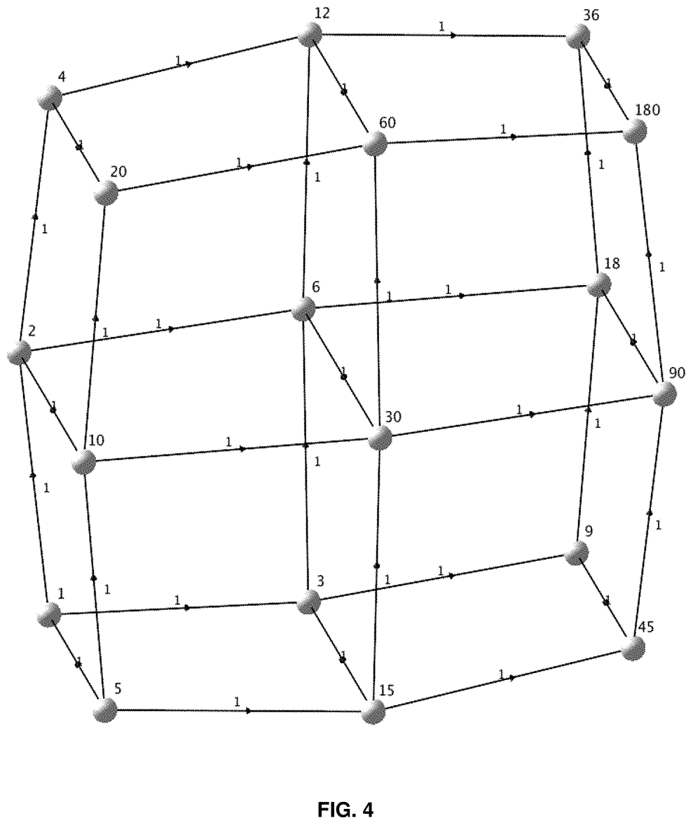

The visualization of the Hasse lattice containing the 6 sets is given in FIG. 4.

The 4-factoring results in 1 quinary equation. The equation is

180=2×3×5×6

The 3-factoring results in 8 quaternary equations. The equations are

$$180 = 2 \times 3 \times 30 = 2 \times 5 \times 18 = 2 \times 6 \times 15 = 2 \times 9 \times 10 = 3 \times 4 \times 15 = 3 \times 5 \times 12 = 3 \times 6 \times 10 = 4 \times 5 \times 9$$

The 2-factoring results in 8 quaternary equations. The equations are

180=2×90=3×60=4×45=5×36=6×30=9×20=10×18=12×15

The disclosed method results in 17 non-trivial canonical equations given in Table II.

TABLE II
exemplilfies the results obtained using the disclosed method when applied on the kind
of quantity energy represented by the orbit representative (0|2, 2, 1, 0, 0, 0, 0) in the
integer lattice [symbol] ₂ × [symbol] ⁷

| i | j | k | l | m | quantity equation |
|---|---|---|---|---|---|
| (0⁷) | (1, 0 [symbol] ) | (0, 0, −1, 0⁴) | (0, 1, 0 [symbol] ) | (1, 0, −1, 0⁴) | E₁ = f₁(Π₁) · s · ω · m · [symbol] |
| (0⁷) | (1, 0 [symbol] ) | (0, 0, −1, 0⁴) | (1, 1, −1, 0⁴) | (0⁷) | E₂ = f₂(Π₂) · s · ω · p |
| (0⁷) | (1, 0 [symbol] ) | (0, 1, 0⁵) | (1, 0, −2, 0⁴) | (0⁷) | E₃ = f₃(Π₃) · s · m · a |
| (0⁷) | (1, 0 [symbol] ) | (1, 0, −1, 0⁴) | (0, 1, −1, 0⁴) | (0⁷) | E₄ = f₄(Π₄) · s · [symbol] · H [symbol] |
| (0⁷) | (1, 0 [symbol] ) | (0, 0, −2, 0⁴) | (1, 1, 0⁴) | (0⁷) | E₅ = f₅(Π₅) · s · ω² · ∫ m ds |
| (0⁷) | (0, 0, −1, 0⁴) | (2, 0⁸) | (0, 1, −1, 0⁴) | (0⁷) | ${E}_{6} = {f}_{6} ( {Π}_{6} ) \cdot ω \cdot {s}^{2} \cdot \frac{\partial m}{\partial t}$ |
| (0⁷) | (0, 0, −1, 0⁴) | (0, 1, 0 [symbol] ) | (2, 0, −1, 0⁴) | (0⁷) | ${E}_{7} = {f}_{7} ( {Π}_{7} ) \cdot ω \cdot m \cdot \frac{\partial A}{\partial t}$ |
| (0⁷) | (0, 0, −1, 0⁴) | (1, 0, −1, 0⁴) | (1, 1, 0 [symbol] ) | (0⁷) | E₈ = f₈(Π₈) · ω · v · ∫ m ds |
| (0⁷) | (2, 0⁸) | (0, 1, 0 [symbol] ) | (0, 0, −2, 0⁴) | (0⁷) | E₉ = f₉(Π₉) · [symbol] · m · ω² |
| (0⁷) | (1, 0 [symbol] ) | (1, 1, −2, 0⁴) | (0⁷) | (0⁷) | E₁₀ = f₁₀(Π₁₀) · [symbol] · F |
| (0⁷) | (0, 0, −1, 0⁴) | (2, 1, −1, 0⁴) | (0⁷) | (0⁷) | E₁₁ = f₁₁(Π₁₁) · ω · L |
| (0⁷) | (2, 0⁴) | (0, 1, −2, 0⁴) | (0⁷) | (0⁷) | ${E}_{12} = {f}_{12} ( {Π}_{12} ) \cdot {s}^{2} \cdot \frac{{\partial }^{2} m}{\partial {t}^{2}}$ |
| (0⁷) | (0, 1, 0⁵) | (2, 0, −2, 0⁴) | (0⁷) | (0⁷) | E₁₃ = f₁₃(Π₁₃) · m · [symbol] |
| (0⁷) | (1, 0, −1, 0⁴) | (1, 1, −1, 0⁴) | (0⁷) | (0⁷) | E₁₄ = f₁₄(Π₁₄) · v · p |
| (0⁷) | (0, 0, −2, 0⁴) | (2, 1, 0⁵) | (0⁷) | (0⁷) | E₁₅ = f₁₅(Π₁₅) · ω² · ∫ ∫ m dA |
| (0⁷) | (1, 1, 0⁴) | (1, 0, −2, 0⁴) | (0⁷) | (0⁷) | E₁₆ = f₁₆(Π₁₆) · a ∫ m ds |
| (0⁷) | (2, 0, −1, 0 [symbol] ) | (0, 1, −1, 0 [symbol] ) | (0⁷) | (0⁷) | ${E}_{17} = {f}_{17} ( {Π}_{17} ) \cdot \frac{\partial A}{\partial t} \cdot \frac{\partial m}{\partial t}$ |

[symbol]

indicates data missing or illegible when filed

The symbols used in the column quantity equation are taken from the dictionary or lexicon (Table III to Table XVIII) of the SI database and have the following interpretation: Eᵢ energy, s displacement, t time, ω angular frequency, m mass, A area, v speed, F force, L total angular momentum, p linear momentum, a acceleration and fᵢ(Πᵢ) function of dimensionless variable.

For the case of the kind of quantity energy we find the 8×8 signed permutation matrix P:

$$P = ( \begin{matrix}1 & 0 & 0 & 0 & 0 & 0 & 0 & 0 \\ 0 & 1 & 0 & 0 & 0 & 0 & 0 & 0 \\ 0 & 0 & 0 & 1 & 0 & 0 & 0 & 0 \\ 0 & 0 & - 1 & 0 & 0 & 0 & 0 & 0 \\ 0 & 0 & 0 & 0 & 1 & 0 & 0 & 0 \\ 0 & 0 & 0 & 0 & 0 & 1 & 0 & 0 \\ 0 & 0 & 0 & 0 & 0 & 0 & 1 & 0 \\ 0 & 0 & 0 & 0 & 0 & 0 & 0 & 1\end{matrix} )$$

Some of the equations, for example equation E₉ representing the form for the harmonic oscillator, E₁₀ representing the form for work, E₁₁ the form of Planck's law and equation E₁₃ representing the form of Einstein's equation, are well-known to engineers and physicists but some of these canonical equations are less known, for example equation E₁₇. The cardinality in [symbol] ₂× [symbol] ⁷ of the set {orb(E)}, labelled by the orbit representative orb(E), is given by the equation

$$card ( \{ orb ( E ) \} ) := 2 ( \frac{{2}^{( 7 - 4 )} 7 !}{1 ! 2 ! 4 !} ) = 1680.$$

So, the computer efficacy of the disclosed method is also in this case very high, as it maps, based on the similitude principle, 1680 engineering problems to 1 canonical problem as given in this embodiment of the kind of quantity energy.

### Example 3

Another embodiment of the disclosed method applied to the field of electromagnetism is the encoding of the vector potential \vec{A} with number G(orb(A))=(−1)⁰2³3²5¹7¹11⁰13⁰17⁰=2520.

This number is known as a highly composite number. Its primordial factorization is 2520=2×6×210.

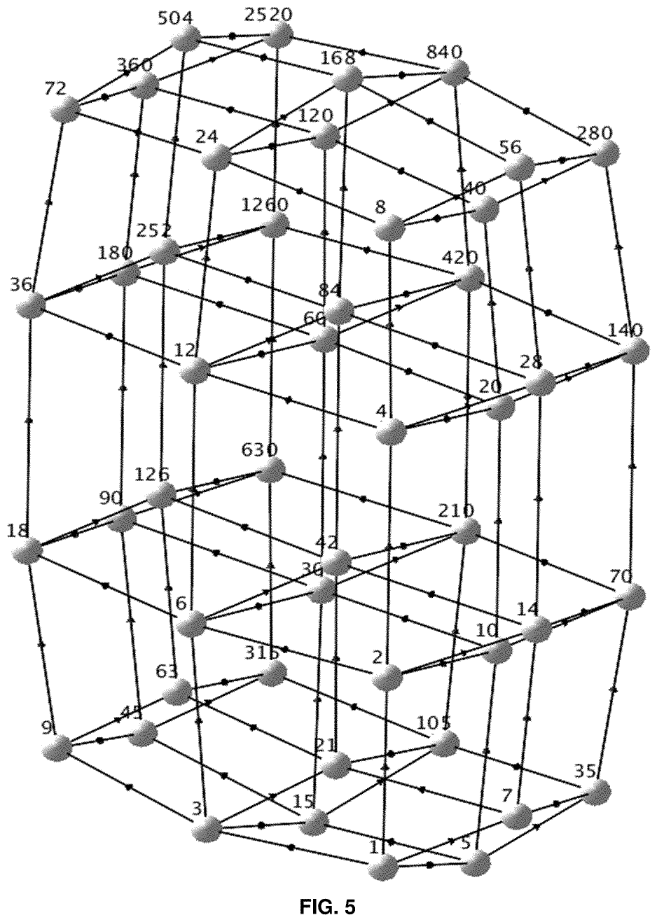

The decoding of the vector potential \vec{A} is summarized through the Hasse diagram given in FIG. 5.

TABLE G.1
Lexicon of published physical quantities in Z₂ × Z⁷.
Table III - Lexicon list 1 of SI database

| # (orbit) | ∥z∥_{∞} | ∥z∥ [symbol] | orthant | physical quantity | Id | orbit | vertex | soc (x) |
|---|---|---|---|---|---|---|---|---|
| 2 | 0 | 0 | 1 | plane angle | 1 | [0⁷] | (0\|0, 0, 0, 0, 0, 0, 0) | 0 |
| 2 | 0 | 0 | 1 | solid angle | 1 | [0⁷] | (0\|0, 0, 0, 0, 0, 0, 0) | 0 |
| 2 | 0 | 0 | 1 | linear strain | 1 | [0⁷] | (0\|0, 0, 0, 0, 0, 0, 0) | 0 |
| 2 | 0 | 0 | 1 | shear strain | 1 | [0⁷] | (0\|0, 0, 0, 0, 0, 0, 0) | 0 |
| 2 | 0 | 0 | 1 | bulk strain | 1 | [0⁷] | (0\|0, 0, 0, 0, 0, 0, 0) | 0 |
| 2 | 0 | 0 | 1 | tensile strain | 1 | [0⁷] | (0\|0, 0, 0, 0, 0, 0, 0) | 0 |
| 2 | 0 | 0 | 1 | relative elongation | 1 | [0⁷] | (0\|0, 0, 0, 0, 0, 0, 0) | 0 |
| 2 | 0 | 0 | 1 | refractive index | 1 | [0⁷] | (0\|0, 0, 0, 0, 0, 0, 0) | 0 |
| 2 | 0 | 0 | 1 | electric susceptibility | 1 | [0⁷] | (0\|0, 0, 0, 0, 0, 0, 0) | 0 |
| 2 | 0 | 0 | 1 | mass ratio | 1 | [0⁷] | (0\|0, 0, 0, 0, 0, 0, 0) | 0 |
| 2 | 0 | 0 | 1 | fine-structure constant (α [symbol] ) | 1 | [0⁷] | (0\|0, 0, 0, 0, 0, 0, 0) | 0 |
| 2 | 0 | 0 | 1 | (α [symbol] ) | 1 | [0⁷] | (0\|0, 0, 0, 0, 0, 0, 0) | 0 |
| 2 | 0 | 0 | 1 | (α [symbol] ) | 1 | [0⁷] | (0\|0, 0, 0, 0, 0, 0, 0) | 0 |
| 2 | 0 | 0 | 1 | (α [symbol] ) | 1 | [0⁷] | (0\|0, 0, 0, 0, 0, 0, 0) | 0 |
| 2 | 0 | 0 | 1 | redshift | 1 | [0⁷] | (0\|0, 0, 0, 0, 0, 0, 0) | 0 |
| 2 | 0 | 0 | 1 | Poisson's ratio | 1 | [0⁷] | (0\|0, 0, 0, 0, 0, 0, 0) | 0 |
| 2 | 0 | 0 | 1 | relative density, specific gravity | 1 | [0⁷] | (0\|0, 0, 0, 0, 0, 0, 0) | 0 |
| 2 | 0 | 0 | 1 | optical depth, optical thickness | 1 | [0⁷] | (0\|0, 0, 0, 0, 0, 0, 0) | 0 |
| 2 | 0 | 0 | 1 | spectral optical depth | 1 | [0⁷] | (0\|0, 0, 0, 0, 0, 0, 0) | 0 |
| 2 | 0 | 0 | 1 | hemispherical emissivity | 1 | [0⁷] | (0\|0, 0, 0, 0, 0, 0, 0) | 0 |
| 2 | 0 | 0 | 1 | spectral hemispherical emissivity | 1 | [0⁷] | (0\|0, 0, 0, 0, 0, 0, 0) | 0 |
| 2 | 0 | 0 | 1 | directional emissivity | 1 | [0⁷] | (0\|0, 0, 0, 0, 0, 0, 0) | 0 |
| . . . | . . . | . . . | . . . | . . . | . . . | . . . | . . . | . . . |

[symbol]

indicates data missing or illegible when filed

TABLE IV
Lexicon list 2 of SI database

| # (orbit) | ∥z∥_{∞} | ∥z∥₁ | orthant | physical quantity | Id | orbit | vertex | soc (x) |
|---|---|---|---|---|---|---|---|---|
| 2 | 0 | 0 | 1 | spectral directional emissivity | 1 | [0⁷] | (0\|0, 0, 0, 0, 0, 0, 0) | 0 |
| 2 | 0 | 0 | 1 | hemispherical absorptance | 1 | [0⁷] | (0\|0, 0, 0, 0, 0, 0, 0) | 0 |
| 2 | 0 | 0 | 1 | spectral hemispherical absorptance | 1 | [0⁷] | (0\|0, 0, 0, 0, 0, 0, 0) | 0 |
| 2 | 0 | 0 | 1 | directional absorptance | 1 | [0⁷] | (0\|0, 0, 0, 0, 0, 0, 0) | 0 |
| 2 | 0 | 0 | 1 | spectral directional absorptance | 1 | [0⁷] | (0\|0, 0, 0, 0, 0, 0, 0) | 0 |
| 2 | 0 | 0 | 1 | hemispherical reflectance | 1 | [0⁷] | (0\|0, 0, 0, 0, 0, 0, 0) | 0 |
| 2 | 0 | 0 | 1 | spectral hemispherical reflectance | 1 | [0⁷] | (0\|0, 0, 0, 0, 0, 0, 0) | 0 |
| 2 | 0 | 0 | 1 | directional reflectance | 1 | [0⁷] | (0\|0, 0, 0, 0, 0, 0, 0) | 0 |
| 2 | 0 | 0 | 1 | spectral directional reflectance | 1 | [0⁷] | (0\|0, 0, 0, 0, 0, 0, 0) | 0 |
| 2 | 0 | 0 | 1 | hemispherical transmittance | 1 | [0⁷] | (0\|0, 0, 0, 0, 0, 0, 0) | 0 |
| 2 | 0 | 0 | 1 | spectral hemispherical transmittance | 1 | [0⁷] | (0\|0, 0, 0, 0, 0, 0, 0) | 0 |
| 2 | 0 | 0 | 1 | directional transmittance | 1 | [0⁷] | (0\|0, 0, 0, 0, 0, 0, 0) | 0 |
| 2 | 0 | 0 | 1 | spectral directional transmittance | 1 | [0⁷] | (0\|0, 0, 0, 0, 0, 0, 0) | 0 |
| 2 | 0 | 0 | 1 | relative gradient, field index | 1 | [0⁷] | (0\|0, 0, 0, 0, 0, 0, 0) | 0 |
| 28 | 1 | 1 | 1 | length | 1 | [10⁶] | (0\|1, 0, 0, 0, 0, 0, 0) | 1 |
| 28 | 1 | 1 | 1 | height | 1 | [10⁶] | (0\|1, 0, 0, 0, 0, 0, 0) | 1 |
| 28 | 1 | 1 | 1 | breadth | 1 | [10⁶] | (0\|1, 0, 0, 0, 0, 0, 0) | 1 |
| 28 | 1 | 1 | 1 | thickness | 1 | [10⁶] | (0\|1, 0, 0, 0, 0, 0, 0) | 1 |
| 28 | 1 | 1 | 1 | distance | 1 | [10⁶] | (0\|1, 0, 0, 0, 0, 0, 0) | 1 |
| 28 | 1 | 1 | 1 | radius | 1 | [10⁶] | (0\|1, 0, 0, 0, 0, 0, 0) | 1 |
| 28 | 1 | 1 | 1 | diameter | 1 | [10⁶] | (0\|1, 0, 0, 0, 0, 0, 0) | 1 |
| 28 | 1 | 1 | 1 | optical path length | 1 | [10⁶] | (0\|1, 0, 0, 0, 0, 0, 0) | 1 |
| 28 | 1 | 1 | 1 | optical path difference | 1 | [10⁶] | (0\|1, 0, 0, 0, 0, 0, 0) | 1 |
| . . . | . . . | . . . | . . . | . . . | . . . | . . . | . . . | . . . |

TABLE V
Lexicon list 3 of SI database

| # (orbit) | ∥z∥_{∞} | ∥z∥₁ | orthant | physical quantity | Id | orbit | vertex | soc (x) |
|---|---|---|---|---|---|---|---|---|
| 28 | 1 | 1 | 1 | mean free path | 1 | [10⁶] | (0\|1, 0, 0, 0, 0, 0, 0) | 1 |
| 28 | 1 | 1 | 1 | persistence length | 1 | [10⁶] | (0\|1, 0, 0, 0, 0, 0, 0) | 1 |
| 28 | 1 | 1 | 1 | effective focal length | 1 | [10⁶] | (0\|1, 0, 0, 0, 0, 0, 0) | 1 |
| 28 | 1 | 1 | 1 | length of arc | 1 | [10⁶] | (0\|1, 0, 0, 0, 0, 0, 0) | 1 |
| 28 | 1 | 1 | 1 | Planck length | 1 | [10⁶] | (0\|1, 0, 0, 0, 0, 0, 0) | 1 |
| 28 | 1 | 1 | 1 | wavelength | 1 | [10⁶] | (0\|1, 0, 0, 0, 0, 0, 0) | 1 |
| 28 | 1 | 1 | 1 | Compton wavelength | 1 | [10⁶] | (0\|1, 0, 0, 0, 0, 0, 0) | 1 |
| 28 | 1 | 1 | 1 | relaxation length | 1 | [10⁶] | (0\|1, 0, 0, 0, 0, 0, 0) | 1 |
| 28 | 1 | 1 | 1 | luminosity distance | 1 | [10⁶] | (0\|1, 0, 0, 0, 0, 0, 0) | 1 |
| 28 | 1 | 1 | 1 | mass | 1 | [10⁶] | (0\|0, 1, 0, 0, 0, 0, 0) | 1 |
| 28 | 1 | 1 | 1 | reduced mass | 1 | [10⁶] | (0\|0, 1, 0, 0, 0, 0, 0) | 1 |
| 28 | 1 | 1 | 1 | Planck mass | 1 | [10⁶] | (0\|0, 1, 0, 0, 0, 0, 0) | 1 |
| 28 | 1 | 1 | 1 | time | 1 | [10⁶] | (0\|0, 0, 1, 0, 0, 0, 0) | 1 |
| 28 | 1 | 1 | 1 | period | 1 | [10⁶] | (0\|0, 0, 1, 0, 0, 0, 0) | 1 |
| 28 | 1 | 1 | 1 | relaxation time | 1 | [10⁶] | (0\|0, 0, 1, 0, 0, 0, 0) | 1 |
| 28 | 1 | 1 | 1 | time constant | 1 | [10⁶] | (0\|0, 0, 1, 0, 0, 0, 0) | 1 |
| 28 | 1 | 1 | 1 | time interval | 1 | [10⁶] | (0\|0, 0, 1, 0, 0, 0, 0) | 1 |
| 28 | 1 | 1 | 1 | proper time | 1 | [10⁶] | (0\|0, 0, 1, 0, 0, 0, 0) | 1 |
| 28 | 1 | 1 | 1 | Planck time | 1 | [10⁶] | (0\|0, 0, 1, 0, 0, 0, 0) | 1 |
| 28 | 1 | 1 | 1 | half-life time | 1 | [10⁶] | (0\|0, 0, 1, 0, 0, 0, 0) | 1 |
| 28 | 1 | 1 | 1 | specific impulse | 1 | [10⁶] | (0\|0, 0, 1, 0, 0, 0, 0) | 1 |
| 28 | 1 | 1 | 1 | electric current | 1 | [10⁶] | (0\|0, 0, 0, 1, 0, 0, 0) | 1 |
| 28 | 1 | 1 | 1 | magnetic potential difference | 1 | [10⁶] | (0\|0, 0, 0, 1, 0, 0, 0) | 1 |
| . . . | . . . | . . . | . . . | . . . | . . . | . . . | . . . | . . . |

TABLE VI
Lexicon list 4 of SI database

| # (orbit) | ∥z∥_{∞} | ∥z∥₁ | orthant | physical quantity | Id | orbit | vertex | soc (x) |
|---|---|---|---|---|---|---|---|---|
| 28 | 1 | 1 | 1 | magnetomotive force | 1 | [10⁶] | (0\|0, 0, 0, 1, 0, 0, 0) | 1 |
| 28 | 1 | 1 | 1 | thermodynamic temperature | 1 | [10⁶] | (0\|0, 0, 0, 0, 1, 0, 0) | 1 |
| 28 | 1 | 1 | 1 | Planck temperature | 1 | [10⁶] | (0\|0, 0, 0, 0, 1, 0, 0) | 1 |
| 28 | 1 | 1 | 1 | amount of substance | 1 | [10⁶] | (0\|0, 0, 0, 0, 0, 1, 0) | 1 |
| 28 | 1 | 1 | 1 | luminous intensity | 1 | [10⁶] | (0\|0, 0, 0, 0, 0, 0, 1) | 1 |
| 28 | 1 | 1 | 1 | luminous flux | 1 | [10⁶] | (0\|0, 0, 0, 0, 0, 0, 1) | 1 |
| 28 | 1 | 1 | 3 | Avogadro constant | 1 | [10⁶] | (0\|0, 0, 0, 0, 0, −1, 0) | −1 |
| 28 | 1 | 1 | 5 | thermal expansion coefficient | 1 | [10⁶] | (0\|0, 0, 0, 0, −1, 0, 0) | −1 |
| 28 | 1 | 1 | 17 | Frequency | 1 | [10⁶] | (0\|0, 0, −1, 0, 0, 0, 0) | −1 |
| 28 | 1 | 1 | 17 | Hubb [symbol] 's constant | 1 | [10⁶] | (0\|0, 0, −1, 0, 0, 0, 0) | −1 |
| 28 | 1 | 1 | 17 | angular frequency | 1 | [10⁶] | (0\|0, 0, −1, 0, 0, 0, 0) | −1 |
| 28 | 1 | 1 | 17 | circular frequency | 1 | [10⁶] | (0\|0, 0, −1, 0, 0, 0, 0) | −1 |
| 28 | 1 | 1 | 17 | activity | 1 | [10⁶] | (0\|0, 0, −1, 0, 0, 0, 0) | −1 |
| 28 | 1 | 1 | 17 | specific material permeability | 1 | [10⁶] | (0\|0, 0, −1, 0, 0, 0, 0) | −1 |
| 28 | 1 | 1 | 17 | angular velocity | 1 | [10⁶] | (0\|0, 0, −1, 0, 0, 0, 0) | −1 |
| 28 | 1 | 1 | 17 | [symbol] | 1 | [10⁶] | (0\|0, 0, −1, 0, 0, 0, 0) | −1 |
| 28 | 1 | 1 | 17 | amount of circulation | 1 | [10⁶] | (0\|0, 0, −1, 0, 0, 0, 0) | −1 |
| 28 | 1 | 1 | 17 | decay constant | 1 | [10⁶] | (0\|0, 0, −1, 0, 0, 0, 0) | −1 |
| 28 | 1 | 1 | 17 | strain rate | 1 | [10⁶] | (0\|0, 0, −1, 0, 0, 0, 0) | −1 |
| 28 | 1 | 1 | 65 | wave number | 1 | [10⁶] | (0\|−1, 0, 0, 0, 0, 0, 0) | −1 |
| 28 | 1 | 1 | 65 | optical power, diopter | 1 | [10⁶] | (0\|−1, 0, 0, 0, 0, 0, 0) | −1 |
| 28 | 1 | 1 | 65 | spatial frequency | 1 | [10⁶] | (0\|−1, 0, 0, 0, 0, 0, 0) | −1 |
| 28 | 1 | 1 | 65 | absorption coefficient | 1 | [10⁶] | (0\|−1, 0, 0, 0, 0, 0, 0) | −1 |
| . . . | . . . | . . . | . . . | . . . | . . . | . . . | . . . | . . . |

[symbol]

indicates data missing or illegible when filed

TABLE VII
Lexicon list 5 of SI database

| # (orbit) | ∥z∥_{∞} | ∥z∥₁ | orthant | physical quantity | Id | orbit | vertex | soc (x) |
|---|---|---|---|---|---|---|---|---|
| 28 | 1 | 1 | 65 | linear attenuation coefficient | 1 | [10⁶] | (0\|−1, 0, 0, 0, 0, 0, 0) | −1 |
| 28 | 1 | 1 | 65 | hemispherical attenuation coefficient | 1 | [10⁶] | (0\|−1, 0, 0, 0, 0, 0, 0) | −1 |
| 28 | 1 | 1 | 65 | spectral hemispherical attenuation coefficient | 1 | [10⁶] | (0\|−1, 0, 0, 0, 0, 0, 0) | −1 |
| 28 | 1 | 1 | 65 | directional attenuation coefficient | 1 | [10⁶] | (0\|−1, 0, 0, 0, 0, 0, 0) | −1 |
| 28 | 1 | 1 | 65 | spectral directional attenuation coefficient | 1 | [10⁶] | (0\|−1, 0, 0, 0, 0, 0, 0) | −1 |
| 28 | 1 | 1 | 65 | laser gain | 1 | [10⁶] | (0\|−1, 0, 0, 0, 0, 0, 0) | −1 |
| 28 | 1 | 1 | 65 | rotational constant | 1 | [10⁶] | (0\|−1, 0, 0, 0, 0, 0, 0) | −1 |
| 28 | 1 | 1 | 65 | Ry [symbol] g constant | 1 | [10⁶] | (0\|−1, 0, 0, 0, 0, 0, 0) | −1 |
| 28 | 2 | 2 | 1 | area | 1 | [20⁶] | (0\|2, 0, 0, 0, 0, 0, 0) | 2 |
| 28 | 2 | 2 | 1 | Thomson cross section | 1 | [20⁶] | (0\|2, 0, 0, 0, 0, 0, 0) | 2 |
| 28 | 2 | 2 | 1 | atomic attenuation coefficient | 1 | [20⁶] | (0\|2, 0, 0, 0, 0, 0, 0) | 2 |
| 28 | 2 | 2 | 17 | angular acceleration | 1 | [20⁶] | (0\|0, 0, −2, 0, 0, 0, 0) | −2 |
| 28 | 2 | 2 | 65 | spacetime curvature | 1 | [20⁶] | (0\|−2, 0, 0, 0, 0, 0, 0) | −2 |
| 28 | 2 | 2 | 65 | integrated luminosity | 1 | [20⁶] | (0\|−2, 0, 0, 0, 0, 0, 0) | −2 |
| 28 | 2 | 2 | 65 | particle [symbol] | 1 | [20⁶] | (0\|−2, 0, 0, 0, 0, 0, 0) | −2 |
| 28 | 3 | 3 | 1 | volume | 1 | [30⁶] | (0\|3, 0, 0, 0, 0, 0, 0) | 3 |
| 28 | 3 | 3 | 17 | angular jerk | 1 | [30⁶] | (0\|0, 0, −3, 0, 0, 0, 0) | −3 |
| 28 | 3 | 3 | 65 | Loschmidt constant | 1 | [30⁶] | (0\|−3, 0, 0, 0, 0, 0, 0) | −3 |
| 28 | 3 | 3 | 65 | number density | 1 | [30⁶] | (0\|−3, 0, 0, 0, 0, 0, 0) | −3 |
| 28 | 3 | 3 | 65 | ion number density | 1 | [30⁶] | (0\|−3, 0, 0, 0, 0, 0, 0) | −3 |
| 28 | 4 | 4 | 1 | second moment of area | 1 | [40⁶] | (0\|4, 0, 0, 0, 0, 0, 0) | 4 |
| 168 | 1 | 2 | 1 | magnetic pole strength | 1 | [1²0⁸] | (0\|1, 0, 0, 1, 0, 0, 0) | 2 |
| 168 | 1 | 2 | 1 | electric charge | 1 | [1²0⁸] | (0\|0, 0, 1, 1, 0, 0, 0) | 2 |
| . . . | . . . | . . . | . . . | . . . | . . . | . . . | . . . | . . . |

[symbol]

indicates data missing or illegible when filed

TABLE VIII
Lexicon list 6 of SI database

| # (orbit) | ∥z∥_{∞} | ∥z∥₁ | orthant | physical quantity | Id | orbit | vertex | soc (x) |
|---|---|---|---|---|---|---|---|---|
| 168 | 1 | 2 | 1 | electric flux | 1 | [1³0 [symbol] ] | (0\|0, 0, 1, 1, 0, 0, 0) | 2 |
| 168 | 1 | 2 | 1 | second radiation constant | 1 | [1²0 [symbol] ] | (0\|1, 0, 0, 0, 1, 0, 0) | 2 |
| 168 | 1 | 2 | 1 | luminous energy | 1 | [1²0 [symbol] ] | (0\|0, 0, 1, 0, 0, 0, 1) | 2 |
| 168 | 1 | 2 | 1 | quantity of light | 1 | [1²0 [symbol] ] | (0\|0, 0, 1, 0, 0, 0, 1) | 2 |
| 168 | 1 | 2 | 3 | molar mass | 1 | [1²0 [symbol] ] | (0\|0, 1, 0, 0, 0, −1, 0) | 0 |
| 168 | 1 | 2 | 17 | linear velocity | 1 | [1²0 [symbol] ] | (0\|1, 0, −1, 0, 0, 0, 0) | 0 |
| 168 | 1 | 2 | 17 | velocity of sound | 1 | [1²0 [symbol] ] | (0\|1, 0, −1, 0, 0, 0, 0) | 0 |
| 168 | 1 | 2 | 17 | group velocity | 1 | [1²0 [symbol] ] | (0\|1, 0, −1, 0, 0, 0, 0) | 0 |
| 168 | 1 | 2 | 17 | volumetric flux | 1 | [1²0 [symbol] ] | (0\|1, 0, −1, 0, 0, 0, 0) | 0 |
| 168 | 1 | 2 | 17 | speed | 1 | [1³0 [symbol] ] | (0\|1, 0, −1, 0, 0, 0, 0) | 0 |
| 168 | 1 | 2 | 17 | speed of light in vacuum | 1 | [1²0 [symbol] ] | (0\|1, 0, −1, 0, 0, 0, 0) | 0 |
| 168 | 1 | 2 | 17 | catalytic activity | 1 | [1²0 [symbol] ] | (0\|0, 0, −1, 0, 0, 1, 0) | 0 |
| 168 | 1 | 2 | 17 | mass flow rate | 1 | [1²0 [symbol] ] | (0\|0, 1, −1, 0, 0, 0, 0) | 0 |
| 168 | 1 | 2 | 17 | mechanical impedance | 1 | [1²0 [symbol] ] | (0\|0, 1, −1, 0, 0, 0, 0) | 0 |
| 168 | 1 | 2 | 17 | spectral exposure in frequency | 1 | [1²0 [symbol] ] | (0\|0, 1, −1, 0, 0, 0, 0) | 0 |
| 168 | 1 | 2 | 33 | molality | 1 | [1²0 [symbol] ] | (0\|0, −1, 0, 0, 0, 1, 0) | 0 |
| 168 | 1 | 2 | 65 | material permeance | 1 | [1²0 [symbol] ] | (0\|−1, 0, 1, 0, 0, 0, 0) | 0 |
| 168 | 1 | 2 | 65 | magnetic held strength | 1 | [1²0 [symbol] ] | (1\|−1, 0, 0, 1, 0, 0, 0) | 0 |
| 168 | 1 | 2 | 65 | magnetisation | 1 | [1²0 [symbol] ] | (1\|−1, 0, 0, 1, 0, 0, 0) | 0 |
| 168 | 1 | 2 | 65 | temperature gradient | 1 | [1²0 [symbol] ] | (0\|−1, 0, 0, 0, 1, 0, 0) | 0 |
| 168 | 1 | 2 | 65 | linear density | 1 | [1²0 [symbol] ] | (0\|−1, 1, 0, 0, 0, 0, 0) | 0 |
| 168 | 2 | 4 | 17 | absorbed dose | 1 | [2²0 [symbol] ] | (0\|2, 0, −2, 0, 0, 0, 0) | 0 |
| 168 | 2 | 4 | 17 | dose equivalent | 1 | [2²0 [symbol] ] | (0\|2, 0, −2, 0, 0, 0, 0) | 0 |
| . . . | . . . | . . . | . . . | . . . | . . . | . . . | . . . | . . . |

[symbol]

indicates data missing or illegible when filed

TABLE IX
Lexicon list 7 of SI database

| # (orbit) | ∥z∥_{∞} | ∥z∥₁ | orthant | physical quantity | Id | orbit | vertex | soc (x) |
|---|---|---|---|---|---|---|---|---|
| 168 | 2 | 4 | 17 | specific energy | 1 | [2²0 [symbol] ] | (0\|2, 0, −2, 0, 0, 0, 0) | 0 |
| 168 | 2 | 4 | 17 | specific enthalpy | 1 | [2²0 [symbol] ] | (0\|2, 0, −2, 0, 0, 0, 0) | 0 |
| 168 | 2 | 4 | 17 | gravitation potential | 1 | [2²0 [symbol] ] | (0\|2, 0, −2, 0, 0, 0, 0) | 0 |
| 336 | 2 | 3 | 1 | magnetic di [symbol] moment | 1 | [210 [symbol] ] | (1\|2, 0, 0, 1, 0, 0, 0) | 3 |
| 336 | 2 | 3 | 1 | electromagnetic moment | 1 | [210 [symbol] ] | (1\|2, 0, 0, 1, 0, 0, 0) | 3 |
| 336 | 2 | 3 | 1 | Bohr magneton | 1 | [210 [symbol] ] | (1\|2, 0, 0, 1, 0, 0, 0) | 3 |
| 336 | 2 | 3 | 1 | moment of inertial | 1 | [210 [symbol] ] | (0\|2, 1, 0, 0, 0, 0, 0) | 3 |
| 336 | 2 | 3 | 1 | instantaneous luminosity | 1 | [210 [symbol] ] | (0\|−2, 0, −1, 0, 0, 0, 0) | −3 |
| 336 | 2 | 3 | 3 | molar attenuation coefficient | 1 | [210 [symbol] ] | (0\|2, 0, 0, 0, 0, −1, 0) | 1 |
| 336 | 2 | 3 | 17 | linear acceleration | 1 | [210 [symbol] ] | (0\|1, 0, −2, 0, 0, 0, 0) | −1 |
| 336 | 2 | 3 | 17 | [symbol] velocity | 1 | [210 [symbol] ] | (0\|2, 0, −1, 0, 0, 0, 0) | 1 |
| 336 | 2 | 3 | 17 | radiant exposure | 1 | [210 [symbol] ] | (0\|0, 1, −2, 0, 0, 0, 0) | −1 |
| 336 | 2 | 3 | 17 | spectral radiance in frequency | 1 | [210 [symbol] ] | (0\|0, 1, −2, 0, 0, 0, 0) | −1 |
| 336 | 2 | 3 | 17 | spectral radiosity in frequency | 1 | [210 [symbol] ] | (0\|0, 1, −2, 0, 0, 0, 0) | −1 |
| 336 | 2 | 3 | 17 | spectral exitance in frequency | 1 | [210 [symbol] ] | (0\|0, 1, −2, 0, 0, 0, 0) | −1 |
| 336 | 2 | 3 | 17 | diffusion constant | 1 | [210 [symbol] ] | (0\|2, 0, −1, 0, 0, 0, 0) | 1 |
| 336 | 2 | 3 | 17 | thermal diffusivity | 1 | [210 [symbol] ] | (0\|2, 0, −1, 0, 0, 0, 0) | 1 |
| 336 | 2 | 3 | 17 | kinematic viscosity | 1 | [210 [symbol] ] | (0\|2, 0, −1, 0, 0, 0, 0) | 1 |
| 336 | 2 | 3 | 17 | quantum of circulation | 1 | [210 [symbol] ] | (0\|2, 0, −1, 0, 0, 0, 0) | 1 |
| 336 | 2 | 3 | 17 | surface tension | 1 | [210 [symbol] ] | (0\|0, 1, −2, 0, 0, 0, 0) | −1 |
| 336 | 2 | 3 | 17 | stiffness | 1 | [210 [symbol] ] | (0\|0, 1, −2, 0, 0, 0, 0) | −1 |
| 336 | 2 | 3 | 33 | mass attenuation coefficient | 1 | [210 [symbol] ] | (0\|2, −1, 0, 0, 0, 0, 0) | 1 |
| 336 | 2 | 3 | 33 | compliance | 1 | [210 [symbol] ] | (0\|0, −1, 2, 0, 0, 0, 0) | 1 |
| . . . | . . . | . . . | . . . | . . . | . . . | . . . | . . . | . . . |

[symbol]

indicates data missing or illegible when filed

TABLE X
Lexicon list 8 of SI database

| # (orbit) | ∥z∥_{∞} | ∥z∥₁ | orthant | physical quantity | Id | orbit | vertex | soc (x) |
|---|---|---|---|---|---|---|---|---|
| 336 | 2 | 3 | 65 | electric current density | 1 | [210 [symbol] ] | (0\|−2, 0, 0, 1, 0, 0, 0) | −1 |
| 336 | 2 | 3 | 65 | surface current density | 1 | [210 [symbol] ] | (0\|−2, 0, 0, 1, 0, 0, 0) | −1 |
| 336 | 2 | 3 | 65 | luminance | 1 | [210 [symbol] ] | (0\|−2, 0, 0, 0, 0, 0, 1) | −1 |
| 336 | 2 | 3 | 65 | illuminance | 1 | [210 [symbol] ] | (0\|−2, 0, 0, 0, 0, 0, 1) | −1 |
| 336 | 2 | 3 | 65 | luminous emittance | 1 | [210 [symbol] ] | (0\|−2, 0, 0, 0, 0, 0, 1) | −1 |
| 336 | 2 | 3 | 65 | photometric irradiance | 1 | [210 [symbol] ] | (0\|−2, 1, 0, 0, 0, 0, 1) | −1 |
| 336 | 2 | 3 | 65 | area density, surface density, | 1 | [210 [symbol] ] | (0\|−2, 0, −1, 0, 0, 0, 0) | −1 |
| | | | | mass thickness | | | | |
| 336 | 2 | 3 | 81 | particle fluence rate | 1 | [210 [symbol] ] | (0\|−2, 0, −1, 0, 0, 0, 0) | −3 |
| 336 | 2 | 3 | 81 | particle flux density | 1 | [210 [symbol] ] | (0\|3, 0, 0, 0, 0, −1, 0) | −3 |
| 336 | 3 | 4 | 3 | molar volume | 1 | [310 [symbol] ] | (0\|0, 1, −3, 0, 0, 0, 0) | 2 |
| 336 | 3 | 4 | 17 | heat flux | 1 | [310 [symbol] ] | (0\|0, 1, −3, 0, 0, 0, 0) | −2 |
| 336 | 3 | 4 | 17 | Poynting vector | 1 | [310 [symbol] ] | (0\|0, 1, −3, 0, 0, 0, 0) | −2 |
| 336 | 3 | 4 | 17 | radiative flux | 1 | [310 [symbol] ] | (0\|0, 1, −3, 0, 0, 0, 0) | −2 |
| 336 | 3 | 4 | 17 | thermal emittance | 1 | [310 [symbol] ] | (0\|0, 1, −3, 0, 0, 0, 0) | −2 |
| 336 | 3 | 4 | 17 | sound intensity | 1 | [310 [symbol] ] | (0\|0, 1, −3, 0, 0, 0, 0) | −2 |
| 336 | 3 | 4 | 17 | radiance | 1 | [310 [symbol] ] | (0\|0, 1, −3, 0, 0, 0, 0) | −2 |
| 336 | 3 | 4 | 17 | irradiance, flux density | 1 | [310 [symbol] ] | (0\|0, 1, −3, 0, 0, 0, 0) | −2 |
| 336 | 3 | 4 | 17 | radiant exitance | 1 | [310 [symbol] ] | (0\|0, 1, −3, 0, 0, 0, 0) | −2 |
| 336 | 3 | 4 | 17 | radiant emittance | 1 | [310 [symbol] ] | (0\|0, 1, −3, 0, 0, 0, 0) | −2 |
| 336 | 3 | 4 | 17 | radiosity | 1 | [310 [symbol] ] | (0\|0, 1, −3, 0, 0, 0, 0) | −2 |
| 336 | 3 | 4 | 17 | energy fluence rate | 1 | [310 [symbol] ] | (0\|0, 1, −3, 0, 0, 0, 0) | −2 |
| 336 | 3 | 4 | 17 | volume rate of flow | 1 | [310 [symbol] ] | (0\|3, 0, −1, 0, 0, 0, 0) | 2 |
| 336 | 3 | 4 | 17 | jerk | 1 | [310 [symbol] ] | (0\|1, 0, −3, 0, 0, 0, 0) | −2 |
| . . . | . . . | . . . | . . . | . . . | . . . | . . . | . . . | . . . |

[symbol]

indicates data missing or illegible when filed

TABLE XI
Lexicon list 9 of SI database

| # (orbit) | ∥z∥_{∞} | ∥z∥₁ | orthant | physical quantity | Id | orbit | vertex | soc (x) |
|---|---|---|---|---|---|---|---|---|
| 336 | 3 | 4 | 33 | specific volume | 1 | [310 [symbol] ] | (0\|3, −1, 0, 0, 0, 0, 0) | 2 |
| 336 | 3 | 4 | 65 | volumetric mass density, specific mass | 1 | [310 [symbol] ] | (0\|−3, 1, 0, 0, 0, 0, 0) | −2 |
| 336 | 3 | 4 | 65 | amount of substance concentration | 1 | [310 [symbol] ] | (0\|−3, 0, 0, 0, 0, 1, 0) | −2 |
| 336 | 3 | 4 | 1 | rate of [symbol] | 1 | [310 [symbol] ] | (0\|−2, 0, −1, 0, 0, 0, 0) | −4 |
| 336 | 3 | 3 | 17 | absorbed dose rate | 2 | [320 [symbol] ] | (0\|2, 0, −3, 0, 0, 0, 0) | −1 |
| 336 | 3 | 3 | 17 | dose equivalent rate | 2 | [320 [symbol] ] | (0\|2, 0, −3, 0, 0, 0, 0) | −1 |
| 336 | 3 | 5 | 17 | specific [symbol] power | 2 | [320 [symbol] ] | (0\|2, 0, −3, 0, 0, 0, 0) | −1 |
| 336 | 4 | 5 | 17 | [symbol] snap | 1 | [410 [symbol] ] | (0\|1, 0, −4, 0, 0, 0, 0) | −3 |
| 336 | 5 | 6 | 17 | crackle | 1 | [510 [symbol] ] | (0\|1, 0, −5, 0, 0, 0, 0) | −4 |
| 336 | 6 | 7 | 17 | pop | 1 | [610 [symbol] ] | (0\|1, 0, −6, 0, 0, 0, 0) | −3 |
| 560 | 1 | 3 | 1 | electric dipole moment | 1 | [1 [symbol] 0 [symbol] ] | (0\|1, 0, 1, 1, 0, 0, 0) | 3 |
| 560 | 1 | 3 | 3 | Faraday constant | 1 | [1 [symbol] 0 [symbol] ] | (0\|0, 0, 1, 1, 0, −1, 0) | 1 |
| 560 | 1 | 3 | 17 | linear momentum | 1 | [1 [symbol] 0 [symbol] ] | (0\|1, 1, −1, 0, 0, 0, 0) | 1 |
| 560 | 1 | 3 | 17 | linear impulse | 1 | [1 [symbol] 0 [symbol] ] | (0\|1, 1, −1, 0, 0, 0, 0) | 1 |
| 560 | 1 | 3 | 25 | vacuum condensate of Higgs field (η) | 1 | [1 [symbol] 0 [symbol] ] | (0\|0, 1, −1, −1, 0, 0, 0) | −1 |
| 560 | 1 | 3 | 33 | fluidity | 1 | [1 [symbol] 0 [symbol] ] | (0\|1, −1, 1, 0, 0, 0, 0) | 1 |
| 560 | 1 | 3 | 33 | magnetogyric ratio | 1 | [1 [symbol] 0 [symbol] ] | (0\|0, −1, 1, 1, 0, 0, 0) | 1 |
| 560 | 1 | 3 | 81 | dynamic viscosity | 1 | [1 [symbol] 0 [symbol] ] | (0\|−1, 1, −1, 0, 0, 0, 0) | −1 |
| 560 | 1 | 3 | 81 | [symbol] density | 1 | [1 [symbol] 0 [symbol] ] | (0\|−1, 1, −1, 0, 0, 0, 0) | −1 |
| 1120 | 1 | 4 | 97 | transport diffusion coefficient | 1 | [1 [symbol] 0 [symbol] ] | (0\|−1, −1, 1, 0, 0, 1, 0) | 0 |
| 1680 | 2 | 4 | 1 | electrical quadrapole moment | 1 | [21 [symbol] 0 [symbol] ] | (0\|2, 0, 1, 1, 0, 0, 0) | 4 |
| 1680 | 2 | 4 | 17 | Force | 1 | [21 [symbol] 0 [symbol] ] | (0\|1, 1, −2, 0, 0, 0, 0) | 0 |
| 1680 | 2 | 4 | 17 | weight | 1 | [21 [symbol] 0 [symbol] ] | (0\|1, 1, −2, 0, 0, 0, 0) | 0 |
| . . . | . . . | . . . | . . . | . . . | . . . | . . . | . . . | . . . |

[symbol]

indicates data missing or illegible when filed

TABLE XII
Lexicon list 10 of SI database

| # (orbit) | ∥z∥_{∞} | ∥z∥₁ | orthant | physical quantity | Id | orbit | vertex | soc (x) |
|---|---|---|---|---|---|---|---|---|
| 1680 | 2 | 4 | 17 | Planck constant | 1 | [21 [symbol] 0 [symbol] ] | (0\|2, 1, −1, 0, 0, 0, 0) | 2 |
| 1680 | 2 | 4 | 17 | angular momentum | 1 | [21 [symbol] 0 [symbol] ] | (1\|2, 1, −1, 0, 0, 0, 0) | 2 |
| 1680 | 2 | 4 | 17 | moment of momentum | 1 | [21 [symbol] 0 [symbol] ] | (1\|2, 1, −1, 0, 0, 0, 0) | 2 |
| 1680 | 2 | 4 | 17 | action | 1 | [21 [symbol] 0 [symbol] ] | (0\|2, 1, −1, 0, 0, 0, 0) | 2 |
| 1680 | 2 | 4 | 17 | spin | 1 | [21 [symbol] 0 [symbol] ] | (0\|2, 1, −1, 0, 0, 0, 0) | 2 |
| 1680 | 2 | 4 | 25 | magnetic flux density | 1 | [21 [symbol] 0 [symbol] ] | (1\|0, 1, −2, −1, 0, 0, 0) | −2 |
| 1680 | 2 | 4 | 25 | magnetic induction | 1 | [21 [symbol] 0 [symbol] ] | (1\|0, 1, −2, −1, 0, 0, 0) | −2 |
| 1680 | 2 | 4 | 25 | magnetic polarization | 1 | [21 [symbol] 0 [symbol] ] | (1\|0, 1, −2, −1, 0, 0, 0) | −2 |
| 1680 | 2 | 4 | 33 | compressibility | 1 | [21 [symbol] 0 [symbol] ] | (0\|1, −1, 2, 0, 0, 0, 0) | 2 |
| 1680 | 2 | 4 | 65 | surface charge density | 1 | [21 [symbol] 0 [symbol] ] | 0\|−2, 0, 1, 1, 0, 0, 0) | 0 |
| 1680 | 2 | 4 | 65 | dielectric polarization | 1 | [21 [symbol] 0 [symbol] ] | 0\|−2, 0, 1, 1, 0, 0, 0) | 0 |
| 1680 | 2 | 4 | 65 | electrical displacement | 1 | [21 [symbol] 0 [symbol] ] | 0\|−2, 0, 1, 1, 0, 0, 0) | 0 |
| 1680 | 2 | 4 | 65 | electric flux density | 1 | [21 [symbol] 0 [symbol] ] | 0\|−2, 0, 1, 1, 0, 0, 0) | 0 |
| 1680 | 2 | 4 | 65 | luminous exposure | 1 | [21 [symbol] 0 [symbol] ] | 0\|−2, 0, 1, 0, 0, 0, 1) | 0 |
| 1680 | 2 | 4 | 81 | energy density | 1 | [21 [symbol] 0 [symbol] ] | (0\|−1, 1, −2, 0, 0, 0, 0) | −2 |
| 1680 | 2 | 4 | 81 | Hamilton density | 1 | [21 [symbol] 0 [symbol] ] | (0\|−1, 1, −2, 0, 0, 0, 0) | −2 |
| 1680 | 2 | 4 | 81 | radiant energy density | 1 | [21 [symbol] 0 [symbol] ] | (0\|−1, 1, −2, 0, 0, 0, 0) | −2 |
| 1680 | 2 | 4 | 81 | spectral exposure in wavelength | 1 | [21 [symbol] 0 [symbol] ] | (0\|−1, 1, −2, 0, 0, 0, 0) | −2 |
| 1680 | 2 | 4 | 81 | sound energy density | 1 | [21 [symbol] 0 [symbol] ] | (0\|−1, 1, −2, 0, 0, 0, 0) | −2 |
| 1680 | 2 | 4 | 81 | toughness | 1 | [21 [symbol] 0 [symbol] ] | (0\|−1, 1, −2, 0, 0, 0, 0) | −2 |
| 1680 | 2 | 4 | 81 | pressure | 1 | [21 [symbol] 0 [symbol] ] | (0\|−1, 1, −2, 0, 0, 0, 0) | −2 |
| 1680 | 2 | 4 | 81 | La [symbol] 's first parameter | 1 | [21 [symbol] 0 [symbol] ] | (0\|−1, 1, −2, 0, 0, 0, 0) | −2 |
| 1680 | 2 | 4 | 81 | La [symbol] 's second parameter | 1 | [21 [symbol] 0 [symbol] ] | (0\|−1, 1, −2, 0, 0, 0, 0) | −2 |
| . . . | . . . | . . . | . . . | . . . | . . . | . . . | . . . | . . . |

[symbol]

indicates data missing or illegible when filed

TABLE XIII
Lexicon list 11 of SI database

| # (orbit) | ∥z∥_{∞} | ∥z∥₁ | orthant | physical quantity | Id | orbit | vertex | soc (x) |
|---|---|---|---|---|---|---|---|---|
| 1680 | 2 | 4 | 81 | P-wave modulus. | 1 | [21²0⁴] | (0\|−1, 1, −2, 0, 0, 0, 0) | −2 |
| 1680 | 2 | 4 | 81 | tensile stress | 1 | [21²0⁴] | (0\|−1, 1, −2, 0, 0, 0, 0) | −2 |
| 1680 | 2 | 4 | 81 | sound pressure | 1 | [21²0⁴] | (0\|−1, 1, −2, 0, 0, 0, 0) | −2 |
| 1680 | 2 | 4 | 81 | modulus of elasticity | 1 | [21²0⁴] | (0\|−1, 1, −2, 0, 0, 0, 0) | −2 |
| 1680 | 2 | 4 | 81 | Young's modulus | 1 | [21²0⁴] | (0\|−1, 1, −2, 0, 0, 0, 0) | −2 |
| 1680 | 2 | 4 | 81 | shear modulus, modulus of rigidity | 1 | [21²0⁴] | (0\|−1, 1, −2, 0, 0, 0, 0) | −2 |
| 1680 | 2 | 4 | 81 | bulk modulus | 1 | [21²0⁴] | (0\|−1, 1, −2, 0, 0, 0, 0) | −2 |
| 1680 | 2 | 4 | 81 | compression modulus | 1 | [21²0⁴] | (0\|−1, 1, −2, 0, 0, 0, 0) | −2 |
| 1680 | 2 | 4 | 81 | normal stress | 1 | [21²0⁴] | (0\|−1, 1, −2, 0, 0, 0, 0) | −2 |
| 1680 | 2 | 4 | 81 | shear stress | 1 | [21²0⁴] | (0\|−1, 1, −2, 0, 0, 0, 0) | −2 |
| 1680 | 2 | 4 | 81 | energy momentum tensor | 1 | [21²0⁴] | (0\|−1, 1, −2, 0, 0, 0, 0) | −2 |
| 1680 | 2 | 4 | 81 | stress energy momentum pseudotensor | 1 | [21²0⁴] | (1\|−1, 1, −2, 0, 0, 0, 0) | −2 |
| 1680 | 2 | 4 | 81 | acoustic impedance | 1 | [21²0⁴] | (0\|−2, 1, −1, 0, 0, 0, 0) | −2 |
| 1630 | 2 | 4 | 81 | mass flux | 1 | [21²0⁴] | (0\|−2, 1, −1, 0, 0, 0, 0) | −2 |
| 1680 | 2 | 4 | 81 | linear impulse density | 1 | [21²0⁴] | (0\|−2, 1, −1, 0, 0, 0, 0) | −2 |
| 1680 | 2 | 5 | 17 | torque | 2 | [2²10⁴] | (1\|2, 1, −2, 0, 0, 0, 0) | 1 |
| 1680 | 2 | 5 | 17 | moment of force | 2 | [2²10⁴] | (0\|2, 1, −2, 0, 0, 0, 0) | 1 |
| 1680 | 2 | 5 | 17 | energy | 2 | [2²10⁴] | (0\|2, 1, −2, 0, 0, 0, 0) | 1 |
| 1680 | 2 | 5 | 17 | radiant energy | 2 | [2²10⁴] | (0\|2, 1, −2, 0, 0, 0, 0) | 1 |
| 1680 | 2 | 5 | 17 | spectral flux in frequency | 2 | [2²10⁴] | (0\|2, 1, −2, 0, 0, 0, 0) | 1 |
| 1680 | 2 | 5 | 17 | spectral intensity in frequency | 2 | [2²10⁴] | (0\|2, 1, −2, 0, 0, 0, 0) | 1 |
| 1680 | 2 | 5 | 17 | potential energy | 2 | [2²10⁴] | (0\|2, 1, −2, 0, 0, 0, 0) | 1 |
| 1680 | 2 | 5 | 17 | kinetic energy | 2 | [2²10⁴] | (0\|2, 1, −2, 0, 0, 0, 0) | 1 |
| . . . | . . . | . . . | . . . | . . . | . . . | . . . | . . . | . . . |

TABLE XIV
Lexicon list 12 of SI database

| # (orbit) | ∥z∥_{∞} | ∥z∥₁ | orthant | physical quantity | Id | orbit | vertex | soc (x) |
|---|---|---|---|---|---|---|---|---|
| 1680 | 2 | 5 | 17 | work | 2 | [2²10⁴] | (0\|2, 1, −2, 0, 0, 0, 0) | 1 |
| 1680 | 2 | 5 | 17 | enthalpy | 2 | [2²10⁴] | (0\|2, 1, −2, 0, 0, 0, 0) | 1 |
| 1680 | 2 | 5 | 17 | Gibbs free energy | 2 | [2²10⁴] | (0\|2, 1, −2, 0, 0, 0, 0) | 1 |
| 1680 | 2 | 5 | 17 | availability | 2 | [2²10⁴] | (0\|2, 1, −2, 0, 0, 0, 0) | 1 |
| 1680 | 2 | 5 | 17 | exergy | 2 | [2²10⁴] | (0\|2, 1, −2, 0, 0, 0, 0) | 1 |
| 1680 | 2 | 5 | 17 | Lagrange function | 2 | [2²10⁴] | (0\|2, 1, −2, 0, 0, 0, 0) | 1 |
| 1680 | 2 | 5 | 17 | Hamilton function | 2 | [2²10⁴] | (0\|2, 1, −2, 0, 0, 0, 0) | 1 |
| 1680 | 2 | 5 | 17 | Hartree energy | 2 | [2²10⁴] | (0\|2, 1, −2, 0, 0, 0, 0) | 1 |
| 1680 | 2 | 5 | 17 | ionization energy | 2 | [2²10⁴] | (0\|2, 1, −2, 0, 0, 0, 0) | 1 |
| 1680 | 2 | 5 | 17 | electron affinity | 2 | [2²10⁴] | (0\|2, 1, −2, 0, 0, 0, 0) | 1 |
| 1680 | 2 | 5 | 17 | electronegativity | 2 | [2²10⁴] | (0\|2, 1, −2, 0, 0, 0, 0) | 1 |
| 1680 | 2 | 5 | 17 | dissociation energy | 2 | [2²10⁴] | (0\|2, 1, −2, 0, 0, 0, 0) | 1 |
| 1680 | 2 | 5 | 21 | specific heat capacity | 2 | [2²10⁴] | (0\|2, 0, −2, 0, −1, 0, 0) | −1 |
| 1680 | 2 | 5 | 21 | specific entropy | 2 | [2²10⁴] | (0\|2, 0, −2, 0, −1, 0, 0) | −1 |
| 1680 | 3 | 5 | 17 | spectral power | 1 | [31²0⁴] | (0\|1, 1, −3, 0, 0, 0, 0) | −1 |
| 1680 | 3 | 5 | 17 | spectral intensity in wavelength | 1 | [31²0⁴] | (0\|1, 1, −3, 0, 0, 0, 0) | −1 |
| 1680 | 3 | 5 | 17 | spectral flux in wavelength | 1 | [31²0⁴] | (0\|1, 1, −3, 0, 0, 0, 0) | −1 |
| 1680 | 3 | 5 | 21 | heat transfer coefficient | 1 | [31²0⁴] | (0\|0, 1, −3, 0, −1, 0, 0) | −3 |
| 1680 | 3 | 5 | 25 | electric field gradient | 1 | [31²0⁴] | (0\|0, 1, −3, −1, 0, 0, 0) | −3 |
| 1680 | 3 | 5 | 33 | thermal insulance | 1 | [31²0⁴] | (0\|0, −1, 3, 0, 1, 0, 0) | 3 |
| 1680 | 3 | 5 | 65 | electric charge density | 1 | [31²0⁴] | (0\|−3, 0, 1, 1, 0, 0, 0) | −1 |
| 1680 | 3 | 5 | 65 | volume charge density | 1 | [31²0⁴] | (0\|−3, 0, 1, 1, 0, 0, 0) | −1 |
| 1680 | 3 | 5 | 65 | luminous energy density | 1 | [31²0⁴] | (0\|−3, 0, 1, 0, 0, 0, 1) | −1 |
| . . . | . . . | . . . | . . . | . . . | . . . | . . . | . . . | . . . |

TABLE XV
Lexicon list 13 of SI database

| # (orbit) | ∥z∥_{∞} | ∥z∥₁ | orthant | physical quantity | Id | orbit | vertex | soc (x) |
|---|---|---|---|---|---|---|---|---|
| 1680 | 3 | 5 | 81 | spectral flux density | 1 | [31²0⁴] | (0\|−1, 1, −3, 0, 0, 0, 0) | −3 |
| 1680 | 3 | 5 | 81 | spectral exitance in wavelength | 1 | [31²0⁴] | (0\|−1, 1, −3, 0, 0, 0, 0) | −3 |
| 1680 | 3 | 5 | 81 | spectral radiance in wavelength | 1 | [31²0⁴] | (0\|−1, 1, −3, 0, 0, 0, 0) | −3 |
| 1680 | 3 | 5 | 81 | spectral irradiance | 1 | [31²0⁴] | (0\|−1, 1, −3, 0, 0, 0, 0) | −3 |
| 1680 | 3 | 5 | 81 | catalytic activity concentration | 1 | [31²0⁴] | (0\|−3, 0, −1, 0, 0, 1, 0) | −3 |
| 1680 | 3 | 5 | 81 | reaction rate | 1 | [31²0⁴] | (0\|−3, 0, −1, 0, 0, 1, 0) | −3 |
| 1680 | 4 | 10 | 97 | Fermi constant | 1 | [4²20⁴] | (0\|−4, −2, 4, 0, 0, 0, 0) | −2 |
| 1680 | 6 | 12 | 17 | 3D phase space volume | 1 | [63³0⁴] | (0\|6, 3, −3, 0, 0, 0, 0) | 6 |
| 3360 | 3 | 6 | 17 | radiant intensity | 1 | [3210²] | (0\|2, 1, −3, 0, 0, 0, 0) | 0 |
| 3360 | 3 | 6 | 17 | radiant flux | 1 | [3210⁴] | (0\|2, 1, −3, 0, 0, 0, 0) | 0 |
| 3360 | 3 | 6 | 17 | power | 1 | [3210⁴] | (0\|2, 1, −3, 0, 0, 0, 0) | 0 |
| 3360 | 3 | 6 | 17 | electric power | 1 | [3210⁴] | (0\|2, 1, −3, 0, 0, 0, 0) | 0 |
| 3360 | 3 | 6 | 17 | sound energy flux | 1 | [3210⁴] | (0\|2, 1, −3, 0, 0, 0, 0) | 0 |
| 3360 | 3 | 6 | 17 | sound power | 1 | [3210⁴] | (0\|2, 1, −3, 0, 0, 0, 0) | 0 |
| 3360 | 3 | 6 | 17 | bolometric luminosity | 1 | [3210⁴] | (0\|2, 1, −3, 0, 0, 0, 0) | 0 |
| 3360 | 3 | 6 | 49 | Newtonian constant of gravitation, universal | 1 | [3210⁴] | (0\|3, −1, −2, 0, 0, 0, 0) | 0 |
| | | | | gravitational constant | | | | |
| 3360 | 4 | 7 | 33 | electric polarizability | 1 | [4210⁴] | (0\|0, −1, 4, 2, 0, 0, 0) | 5 |
| 3360 | 4 | 8 | 17 | first radiation constant | 2 | [4310⁴] | (0\|4, 1, −3, 0, 0, 0, 0) | 2 |
| 3360 | 4 | 8 | 21 | Stefan-Boltzmann constant | 2 | [4310⁴] | (0\|0, 1, −3, 0, −4, 0, 0) | −6 |
| 4480 | 2 | 5 | 17 | molar Planck constant | 1 | [21²0³] | (0\|2, 1, −1, 0, 0, −1, 0) | 1 |
| 4480 | 2 | 5 | 25 | magnetic vector potential | 1 | [21³0³] | (0\|1, 1, −2, −1, 0, 0, 0) | −1 |
| 4480 | 2 | 7 | 25 | inductance | 2 | [2³10³] | (0\|2, 1, −2, −2, 0, 0, 0) | −1 |
| . . . | . . . | . . . | . . . | . . . | . . . | . . . | . . . | . . . |

TABLE XVI
Lexicon list 14 of SI database

| # (orbit) | ∥z∥_{∞} | ∥z∥₁ | orthant | physical quantity | Id | orbit | vertex | soc (x) |
|---|---|---|---|---|---|---|---|---|
| 4480 | 2 | 7 | 25 | self-inductance | 2 | [2³10³] | (0\|2, 1, −2, −2, 0, 0, 0) | −1 |
| 4480 | 2 | 7 | 25 | magnetic permeance | 2 | [2³10³] | (0\|2, 1, −2, −2, 0, 0, 0) | −1 |
| 4480 | 2 | 7 | 25 | mutual inductance | 2 | [2³10³] | (0\|2, 1, −2, −2, 0, 0, 0) | −1 |
| 4480 | 2 | 7 | 33 | magnetizability | 2 | [2³10³] | (0\|2, −1, 2, 2, 0, 0, 0) | 5 |
| 4480 | 2 | 7 | 97 | magnetic reluctance | 2 | [2³10³] | (0\|−2, −1, 2, 2, 0, 0, 0) | 1 |
| 4480 | 3 | 6 | 21 | thermal conductivity | 1 | [31³0³] | (0\|1, 1, −3, 0, −1, 0, 0) | −2 |
| 4480 | 3 | 6 | 25 | electric field strength | 1 | [31³0³] | (0\|1, 1, −3, −1, 0, 0, 0) | −2 |
| 4480 | 3 | 6 | 97 | thermal resistivity | 1 | [31³0³] | (0\|−1, −1, 3, 0, 1, 0, 0) | 2 |
| 4480 | 3 | 6 | 97 | first hyper-susceptibility | 1 | [31³0³] | (0\|−1, −1, 3, 1, 0, 0, 0) | 2 |
| 4480 | 6 | 12 | 97 | second hyper-susceptibility | 1 | [62³0³] | (0\|−2, −2, 6, 2, 0, 0, 0) | 4 |
| 6720 | 2 | 6 | 19 | chemical potential | 1 | [2²1²0³] | (0\|2, 1, −2, 0, 0, −1, 0) | 0 |
| 6720 | 2 | 6 | 19 | molar energy | 1 | [2²1²0³] | (0\|2, 1, −2, 0, 0, −1, 0) | 0 |
| 6720 | 2 | 6 | 19 | activation energy | 1 | [2²1²0³] | (0\|2, 1, −2, 0, 0, −1, 0) | 0 |
| 6720 | 2 | 6 | 21 | entropy | 1 | [2²1²0³] | (0\|2, 1, −2, 0, −1, 0, 0) | 0 |
| 6720 | 2 | 6 | 21 | heat capacity | 1 | [2²1²0³] | (0\|2, 1, −2, 0, −1, 0, 0) | 0 |
| 6720 | 2 | 6 | 21 | Boltzmann constant | 1 | [2²1²0³] | (0\|2, 1, −2, 0, −1, 0, 0) | 0 |
| 6720 | 2 | 6 | 25 | magnetic flux quantum | 1 | [2²1²0³] | (0\|2, 1, −2, −1, 0, 0, 0) | 0 |
| 6720 | 2 | 6 | 25 | magnetic constant | 1 | [2²1²0³] | (0\|1, 1, −2, −2, 0, 0, 0) | −2 |
| 6720 | 2 | 6 | 25 | permeability | 1 | [2²1²0³] | (0\|1, 1, −2, −2, 0, 0, 0) | −2 |
| 6720 | 2 | 6 | 25 | magnetic flux | 1 | [2²1²0³] | (0\|2, 1, −2, −1, 0, 0, 0) | 0 |
| 6720 | 2 | 6 | 25 | magnetic moment | 1 | [2²1²0³] | (0\|2, 1, −2, −1, 0, 0, 0) | 0 |
| 6720 | 2 | 6 | 97 | Josephson constant | 1 | [2²1²0³] | (0\|−2, −1, 2, 1, 0, 0, 0) | 0 |
| 6720 | 3 | 8 | 25 | specific resistance | 1 | [3³1³0³] | (0\|3, 1, −3, −1, 0, 0, 0) | 0 |
| . . . | . . . | . . . | . . . | . . . | . . . | . . . | . . . | . . . |

TABLE XVII
Lexicon list 15 of SI database

| # (orbit) | ∥z∥_{∞} | ∥z∥₁ | orthant | physical quantity | Id | orbit | vertex | soc (x) |
|---|---|---|---|---|---|---|---|---|
| 4480 | 2 | 7 | 25 | self-inductance | 2 | [2³10³] | (0\|2, 1, −2, −2, 0, 0, 0) | −1 |
| 4480 | 2 | 7 | 25 | magnetic permeance | 2 | [2³10³] | (0\|2, 1, −2, −2, 0, 0, 0) | −1 |
| 4480 | 2 | 7 | 25 | mutual inductance | 2 | [2³10³] | (0\|2, 1, −2, −2, 0, 0, 0) | −1 |
| 4480 | 2 | 7 | 33 | magnetizability | 2 | [2³10³] | (0\|2, −1, 2, 2, 0, 0, 0) | 5 |
| 4480 | 2 | 7 | 97 | magnetic reluctance | 2 | [2³10³] | (0\|−2, −1, 2, 2, 0, 0, 0) | 1 |
| 4480 | 3 | 6 | 21 | thermal conductivity | 1 | [31³0³] | (0\|1, 1, −3, 0, −1, 0, 0) | −2 |
| 4480 | 3 | 6 | 25 | electric field strength | 1 | [31³0³] | (0\|1, 1, −3, −1, 0, 0, 0) | −2 |
| 4480 | 3 | 6 | 97 | thermal resistivity | 1 | [31³0³] | (0\|−1, −1, 3, 0, 1, 0, 0) | 2 |
| 4480 | 3 | 6 | 97 | first hyper-susceptibility | 1 | [31³0³] | (0\|−1, −1, 3, 1, 0, 0, 0) | 2 |
| 4480 | 6 | 12 | 97 | second hyper-susceptibility | 1 | [62³0³] | (0\|−2, −2, 6, 2, 0, 0, 0) | 4 |
| 6720 | 2 | 6 | 19 | chemical potential | 1 | [2²1²0³] | (0\|2, 1, −2, 0, 0, −1, 0) | 0 |
| 6720 | 2 | 6 | 19 | molar energy | 1 | [2²1²0³] | (0\|2, 1, −2, 0, 0, −1, 0) | 0 |
| 6720 | 2 | 6 | 19 | activation energy | 1 | [2²1²0³] | (0\|2, 1, −2, 0, 0, −1, 0) | 0 |
| 6720 | 2 | 6 | 21 | entropy | 1 | [2²1²0³] | (0\|2, 1, −2, 0, −1, 0, 0) | 0 |
| 6720 | 2 | 6 | 21 | heat capacity | 1 | [2²1²0³] | (0\|2, 1, −2, 0, −1, 0, 0) | 0 |
| 6720 | 2 | 6 | 21 | Boltzmann constant | 1 | [2²1²0³] | (0\|2, 1, −2, 0, −1, 0, 0) | 0 |
| 6720 | 2 | 6 | 25 | magnetic flux quantum | 1 | [2²1²0³] | (0\|2, 1, −2, −1, 0, 0, 0) | 0 |
| 6720 | 2 | 6 | 25 | magnetic constant | 1 | [2²1²0³] | (0\|1, 1, −2, −2, 0, 0, 0) | −2 |
| 6720 | 2 | 6 | 25 | permeability | 1 | [2²1²0³] | (0\|1, 1, −2, −2, 0, 0, 0) | −2 |
| 6720 | 2 | 6 | 25 | magnetic flux | 1 | [2²1²0³] | (0\|2, 1, −2, −1, 0, 0, 0); | 0 |
| 6720 | 2 | 6 | 25 | magnetic moment | 1 | [2²1²0³] | (0\|2, 1, −2, −1, 0, 0, 0) | 0 |
| 6720 | 2 | 6 | 97 | Josephson constant | 1 | [2²1²0³] | (0\|−2, −1, 2, 1, 0, 0, 0) | 0 |
| 6720 | 3 | 8 | 25 | specific resistance | 1 | [3³1³0³] | (0\|3, 1, −3, −1, 0, 0, 0) | 0 |
| . . . | . . . | . . . | . . . | . . . | . . . | . . . | . . . | . . . |

TABLE XVIII
Lexicon list 16 of SI database

| # (orbit) | ∥z∥_{∞} | ∥z∥₁ | orthant | physical quantity | Id | orbit | vertex | soc (x) |
|---|---|---|---|---|---|---|---|---|
| 13440 | 4 | 9 | 97 | electric capacitance | 2 | [42²10³] | (0\|−2, −1, 4, 2, 0, 0, 0) | 3 |
| 26880 | 4 | 10 | 97 | electric constant | 1 | [43210³] | (0\|−3, −1, 4, 2, 0, 0, 0) | 2 |
| 26880 | 4 | 10 | 97 | permittivity | 1 | [43210³] | (0\|−3, −1, 4, 2, 0, 0, 0) | 2 |
| 26880 | 7 | 13 | 97 | first hyper-polarizability | 1 | [73210³] | (0\|−1, −2, 7, 3, 0, 0, 0) | 7 |
| 26880 | 10 | 19 | 97 | second hyper-polarizability | 1 | [(10)4320³] | (0\|−2, −3, 10, 4, 0, 0, 0) | 9 |

What is claimed is:

1. A machine-implementable method for forming quantity equations from a selection of a set or sets of dependent and independent variables, comprising the steps of:
a) defining an input from a selection of a set or sets of dependent and independent variables, the input comprising a list of quantities;
b) processing said input, comprising the steps of encoding and decoding of dimensionless groups in an integer lattice, preferably using integer factorization techniques, thereby obtaining a system of quantity equations, the quantity equations comprising the quantities; and,
c) presenting the system of quantity equations as output.

2. The method according to claim 1, wherein step a) comprises the steps of:
choosing a list of quantities by selecting and ordering n base quantities;
selecting w quantities from the said list of quantities to be analyzed where w is a natural number; and,
comparing the w quantities to a ‘kind of quantity’ database to determine the corresponding w integer lattice points of [symbol] ₂× [symbol] ⁿ.

3. The method according to claim 1, wherein a quantity is selected that maps to the orbit representative with integer lattice point x=(0|n,n−1, . . . ,1) of [symbol] ₂× [symbol] ⁿ of largest cardinality equal to the order 2(2ⁿn!) of the integer lattice [symbol] ₂× [symbol] ⁿ.

4. The method according to claim 1, wherein step b) comprises the steps of:
calculating for each of the w integer lattice points their respective w orbit representative orb(xᵢ), by taking the absolute value of the coordinates of the integer lattice point xᵢ=(x₀ⁱ|x₁ⁱ, . . . ,xₙⁱ), sorting them in decreasing order and renaming the coordinates such that orb(xᵢ)=(z₀ⁱ|z₁ⁱ, . . . ,zₙⁱ) where z₁ⁱ≥z₂ⁱ≥ . . . ≥zₙⁱ and where i∈{1, . . . , w};
calculating for the w orbit representatives their respective degree dᵢ, where i∈ {1, . . . , w};
identifying the orbit representative with the largest degree, denoting it y, and recalling its associated integer lattice point denoted as xₛ, such that y=orb(xₛ);
encoding each orbit representative orb(xᵢ) using the prescription:
$$G ( orb ( {x}_{i} ) ) := {( - 1 )}^{{z}_{0}^{i}} {p}_{1}^{{z}_{1}^{i}} ⋯ {p}_{n}^{{z}_{n}^{i}}$$
where pᵢ^{z}^{ᵢ} is the zᵢ-th power of the i-th prime number and where i∈{1, . . . , w};
generating the divisors sets of the w integers G(orb(xᵢ));
performing the m-factorization of the integer G(orb(xᵢ)) in distinct factors Fⱼ where j∈{1, . . . , m},
calculating the prime factorization of each distinct factor Fⱼ;
decoding each m-factorization of the integer G(orb(xᵢ)) following the prescription:
$${F}_{j} := {( - 1 )}^{{z}_{0}^{j}} {p}_{1}^{{z}_{1}^{j}} ⋯ {p}_{n}^{{z}_{n}^{j}} \to ( {z}_{0}^{j} \vert {z}_{1}^{j} , ⋯ , {z}_{n}^{j} )$$
to obtain an additive partitioning using the respective prime factorizations of each distinct factor Fⱼ and replacing the multiplication operator ‘x’ by the addition operator ‘+’ obtaining (m+1)-ary vector equations in the integer lattice [symbol] ₂× [symbol] ⁿ;
calculating the (n+1)×(n+1) signed permutation matrix P that maps the orbit representative y to the integer lattice point xₛ of [symbol] ₂× [symbol] ⁿ such that y=P [symbol] where [symbol] is the transposed vector of the integer lattice point xₛ; and,
multiplying each (m+1)-ary vector equation with the (n+1)×(n+1) signed permutation matrix P to obtain the final system of vector equations in the integer lattice [symbol] ₂× [symbol] ⁿ.

5. The method according to claim 4, wherein step b) comprises the steps of:
selecting the w integers G(orb(xᵢ));
ordering the divisors sets of the integers G(orb(xᵢ)) in their subsets of equal degree;
building a division lattice for each of the integers G(orb(xᵢ)) by stacking the subsets from low to high degree; and,
taking the union of the w division lattices.

6. The method according to claim 5, wherein step b) comprises the steps of:
selecting the p-norm;
calculating the p-norm between all the lattice points generated by the union of the division lattices; and,
visualizing the Euclidean graph for said p-norm of all the lattice points generated by said union of the division lattices.

7. The method according to claim 5, wherein step b) comprises the steps of:
selecting the 2-norm;
calculating the 2-norm between all the lattice points generated by the union of the division lattices; and,
visualizing the Euclidean graph for said 2-norm of all the lattice points generated by said union of the division lattices.

8. The method according to claim 5, wherein step b) comprises the steps of:
selecting the square of the 2-norm;
calculating the square of the 2-norm between all the lattice points generated by the union of the division lattices; and,
visualizing the Euclidean graph for said square of the 2-norm of all the lattice points generated by said union of the division lattices.

9. The method according to claim 1, wherein step c) comprises the step of:
creating a system of equations from the vector equations of the integer lattice [symbol] ₂× [symbol] ⁿ, preferably wherein the system of equations comprises algebraic equations, and/or ordinary differential equations, and/or partial differential equations, and/or integro-differential equations.

10. The method according to claim 1, wherein step c) comprises the step of:
labelling the variables using a lexicon, preferably a lexicon of the SI database.

11. The method according to claim 10, wherein the lexicon is based on another system of units than the SI database.

12. The method according to claim 1, wherein step c) comprises the steps of:
updating a global lexicon or dictionary with the output of the method according to claim 1;
analyzing the results through viewing information, visualizations, graphs, tables, and the like; and,
optionally, providing extra information if the quantity equations are known.

13. The method according to claim 2, wherein the dimension n=7 with the ordered base vectors being length, mass, time, electric current, thermodynamic temperature, amount of substance, and luminous intensity, starting from coordinate index 1 and ending with index 7, and wherein the coordinate index 0 is reserved for the tensor type of the physical quantity;
or, wherein the dimension n=1 with the ordered base vector being length, starting from coordinate index 1 and ending with index 1, and wherein the coordinate index 0 is reserved for the tensor type of the physical quantity;
or, wherein the dimension n=2 with the ordered base vectors being length, mass starting from coordinate index 1 and ending with index 2 and wherein the coordinate index 0 is reserved for the tensor type of the physical quantity;
or, wherein the dimension n=3 with the ordered base vectors being length, mass, and time, starting from coordinate index 1 and ending with index 3, and wherein the coordinate index 0 is reserved for the tensor type of the physical quantity;
or, wherein the dimension n=4 with the ordered base vectors being length, mass, time, and electric current, starting from coordinate index 1 and ending with index 4, and wherein the coordinate index 0 is reserved for the tensor type of the physical quantity;
or, wherein the dimension n=5 with the ordered base vectors being length, mass, time, electric current, and thermodynamic temperature, starting from coordinate index 1 and ending with index 5, and wherein the coordinate index 0 is reserved for the tensor type of the physical quantity;
or, wherein the dimension n=6 with the ordered base vectors being length, mass, time, electric current, thermodynamic temperature, and amount of substance, starting from coordinate index 1 and ending with index 6, and wherein the coordinate index 0 is reserved for the tensor type of the physical quantity.

14. Use of the method according to claim 1 for an engineering problem.

15. A system for forming quantity equations from a selection of a set of independent variables, preferably for engineering problems, comprising a computing device that includes a computer-readable storage medium storing a computer program, the computer program being configured to cause the computer to perform the method according to claim 1.
